(19) United States
(12) Patent Application Publication
(10) Pub. No.: US 2025/0149855 A1
(43) Pub. Date: May 8, 2025

(54) SYSTEMS AND METHODS FOR SCALING ELECTROMAGNETIC APERTURES, SINGLE MODE LASERS, AND OPEN WAVE SYSTEMS

(71) Applicant: THE REGENTS OF THE UNIVERSITY OF CALIFORNIA, Oakland, CA (US)

(72) Inventors: Boubacar KANTE, Berkeley, CA (US); Rushin MANAN CONTRACTOR, Berkeley, CA (US); Wanwoo NOH, Berkeley, CA (US); Walid REDJEM, Berkeley, CA (US)

(21) Appl. No.: 18/833,471

(22) PCT Filed: Jan. 30, 2023
(86) PCT No.: PCT/US2023/011879

§ 371 Date: Jul. 26, 2024

Related U.S. Application Data
(60) Provisional application No. 63/304,581, filed on Jan. 29, 2022.

(51) Int. Cl. H01S 5/11; H01S 5/00; H01S 5/024; H01S 5/10

(52) U.S. Cl. CPC H01S 5/11; H01S 5/0014; H01S 5/02469; H01S 5/1042; H01S 2301/163

(57) ABSTRACT

A surface-emitting, single mode laser includes a gain medium and a photonic structure. The gain medium is configured to emit an electromagnetic wave. The photonic structure is electromagnetically coupled to the gain medium and has a cavity mode-dependent scaling of losses so that higher order modes are coupled to more lossy bands and a fundamental mode, at a high symmetry point, is coupled to a less lossy band of the photonic structure.

### GOVERNMENT FUNDING

This invention was funded by an award from the Office of Naval Research, award number N00014-19-1-2737. The government has certain right in the invention.

### BACKGROUND

Surface emitting lasers and high-power surface emitting lasers are important for numerous applications in telecommunication, biology, sensing, or in defense. Current techniques for single mode lasers with single apertures that are lightweight, small, and efficient fail quickly as the size of the aperture increases. This failure is due to rapid multimode operation when the size of the aperture is increased. This have been a challenge for the last 60 years.

Scalable surface emitting lasers such as described herein may have applications in Lidar for self-driving cars, in cabin sensing, consumer electronics such as smartphones, optical communications (long-haul, medium distance and short distance interconnects) and medical devices, to cite just a few potential applications.

### SUMMARY

The power of single aperture (finite sized surface) lasers scale with the size of the aperture (surface area). Fundamentally, the laser becomes multimode when the surface area increases. The systems and techniques describe herein address this long-standing problem and can now make a single aperture single mode regardless of the aperture size. The aperture is compact in size, lightweight, and power efficient. In one aspect, the methods described herein constitute a systematic method to increase the power of surface emitting lasers.

In another aspect, a scalable laser aperture that emit light perpendicular to the surface and that can be in principle scaled up to arbitrarily large sizes is provided. The aperture may thus be a universal solution to laser power scaling as it can be used for systems in need of small, intermediate, or high power, using the same architecture. Solutions to this challenge use what is referred to herein as an open-Dirac electromagnetic aperture or Berkeley Surface Emitting Laser (BKSEL). Our structures are based on photonic crystal apertures or nanostructured apertures that exhibit a quasi-linear dispersion at the center of the Brillouin zone together with a mode dependent loss controlled by the cavity boundaries, modes, and crystal truncation. The open Dirac cavities protect the fundamental mode and couple higher order modes to lossy bands of the photonic structure.

The scaling of electromagnetic apertures is a long-standing question that has been investigated for at least six decades. The size of single aperture cavities, bounded by the existence of higher order transverse modes, fundamentally limits the power emitted by single-mode lasers or the brightness of quantum light sources. The challenge prompted the investigation of vertical surface emitting laser (VCSELs), VCSEL arrays, multilayered engineered photonic crystals etc.

The fundamental challenge stems from the fact that electromagnetic apertures support cavity modes that rapidly become arbitrarily close with the size of the aperture. The free-spectral range of existing electromagnetic apertures goes to zero when the size of the aperture increases, and the demonstration of scale-invariant apertures or lasers has remained elusive. We show open-Dirac electromagnetic apertures that exploit the linear dispersion of photons at the center of the Brillouin zone together and a subtle cavity-mode-dependent scaling of losses. For cavities with a quadratic dispersion, detuned from the Dirac singularity, the complex frequencies of modes of finite sized cavities converge towards each other with the size of cavities, making them multimode.

Surprisingly, for a class of cavities with linear dispersion, we found that while the convergence of the real parts of cavity modes towards each other is delayed (it also quickly goes to zero), the normalized complex free-spectral range converge towards a constant solely governed by the loss rate of Bloch bands. We show that this unique scaling of the complex frequency of cavity modes in open-Dirac electromagnetic apertures guarantees single-mode operation of large cavities. We experimentally demonstrate single-mode lasing of scaled up, limited only by manufacturing. The lasing mode is also confirmed from far-field measurements. The results indicate that there is no limit to how large an electromagnetic aperture can be and thus enable applications wherever small size, power, and lightweight devices and sources are needed.

Surface-emitting lasers have shown great promise in recent times due to their advantages in scalability over the commercially widespread vertical-cavity surface-emitting lasers (VCSELs). When a photonic crystal is truncated to a finite cavity, the continuous bands break up into discrete cavity modes. These higher order modes compete with the fundamental lasing mode and the device becomes more susceptible to multimode lasing response as the cavity size increases.

Currently available lasers fail at a relatively small scale on the order of tens of microns and become multimode as the scale increases. The lasers described herein have apertures that can be scaled arbitrarily and maintain single transverse mode. The scalable aperture can be implemented in any frequency range from microwaves, terahertz, infrared, optics and beyond. In various embodiments, the laser may have one or more of the following advantages: the scalable aperture laser may be thin, compact and lightweight; the scalable laser may be efficient because power is emitted from all material in the aperture; the fundamental mode depletes gain for other modes; the scalable laser can be pumped both electrically and optically; the scalable aperture may contain structures that are on the order of the wavelength or smaller and thus requires nano structuring that is within reach of conventional fabrication techniques such as CMOS nanofabrication techniques.

In some implementations the scalable laser can be integrated in silicon or other CMOS devices for light emission out of the chip. The scalable laser can be used in various applications, including to manipulate cells and biological substances for trapping and in application for lidars, and especially in applications where the efficiency and the weight are critical, such as in mobility applications or applications in laser surgery where the laser needs to be inserted in a small volume. The scalable laser also can be directly integrated with sensors for environmental monitoring as a single laser or as an array of lasers. An array of the scalable lasers can be placed in the focal plane of an imaging system to implement electronically controlled beam steering for lidars.

In other implementations the scalable laser can be inserted in a pn junction for making electrically pumped single mode lasers. The scalable laser can be used with dye molecules for lasing using organic materials. In another implementation the scalable laser invention can be used to control electromagnetic emission from materials. It can also be used to scale up any open system based on waves such as acoustic, quantum, or electronic systems.

In yet other implementations the scalable laser can be directly pumped optically as a diode.

### BRIEF DESCRIPTION OF THE DRAWINGS

FIGS. 1(a)-1(e) show examples of open-Dirac apertures; and FIGS. 1(f) and 1(g) show the photonic bands and their purity near the center of the Brillouin zone when the design parameter d is not tuned close to a degeneracy and when d is tuned to a degeneracy, respectively.

FIGS. 2(a) and 2(b) show side-views of surface emitting cavities with the electromagnetic mode profile superimposed for conventional apertures (FIG. 2a) and the Dirac aperture (FIG. 2b); and FIGS. 2c-2g show a top-view of the Dirac apertures.

FIGS. 3(a)-3(h) are graphs illustrating the scaling of frequency and loss rate for the Dirac aperture.

FIGS. 4(a)-4(d) show side views of illustrative examples of the scalable surface-emitting layer in which the active medium is a multi-quantum well (MQW).

FIGS. 5(a)-5(c) show side views of illustrative examples of the scalable surface-emitting layer with various examples of heat extraction schemes using thermos-cooling or substrate cooling.

FIGS. 6(a)-6(c) show data for fabricated surface-emitting devices with different aperture sizes and the corresponding photoluminescence spectrum and far field.

FIGS. 7(a)-7(d) show experimental Fourier space images of the laser emission (top) and near field from numerical simulations (bottom) for cavities with a length of 11 unit cells (FIG. 7a), 19 unit cells (FIG. 7b), 27 unit cells (FIGS. 7c), and 35 unit cells (FIG. 7d).

FIGS. 8(a)-8(c) show examples of scalable open-Dirac electromagnetic cavities.

FIGS. 9(a)-9(m) illustrate the complex frequency scaling of open-Dirac electromagnetic cavities.

FIGS. 10(a)-10(l) illustrate the lasing characteristics of BerkSELs around the Dirac singularity.

FIGS. 11(a)-11(g) show photon statistics and far-field of BerkSELs.

FIG. 12 is a graph illustrating the frequency dependence of the A1, B1, E1, and E2 modes at the Γ-point as a function of the normalized air hole radii r/a, where r is the radius and a the period, for a triangular lattice of an InGaAsP slab.

FIG. 13(a) illustrates the dispersion of a photonic crystal at the critical radius showing linear dispersion at Γ and FIG. 13(b) shows the corresponding quality factor.

FIGS. 14(a)-14(d) show the dispersion of the real and imaginary part of the eigenvalues for the two degenerate modes B₁ and E₂.

FIGS. 15(a)-15(d) illustrate the scaling of the frequency and inverse of the complex frequency for the three cavity modes.

FIGS. 16(a)-16(f) illustrate one example of a nanofabrication process that may be used to form the open-Dirac electromagnetic cavities described herein.

FIG. 17 shows a photoluminescence (PL) measurement apparatus that was used to characterize fabricated devices.

FIG. 18 shows the emission spectra from the BerkSEL (L=35a).

FIG. 19(a) shows an example of an experimental coincidence histogram and FIG. 19 shows a zoomed view on the zero-delay pulse superimposedwith a side pulse.

FIGS. 20(a)-20(c) show the second-order intensity correlation g²(τ) for three different pump powers.

### DETAILED DESCRIPTION

### Introduction

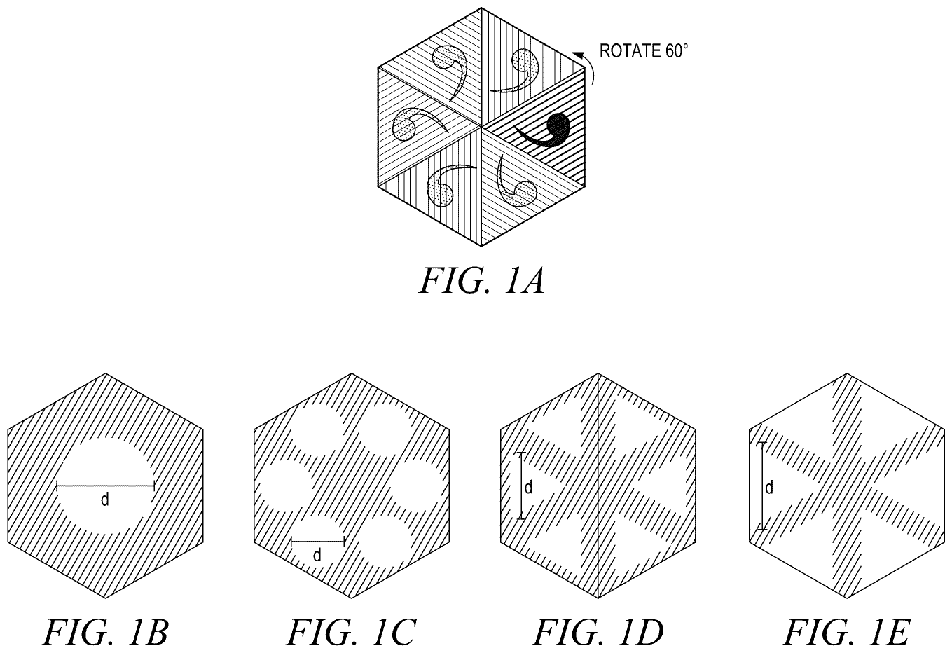

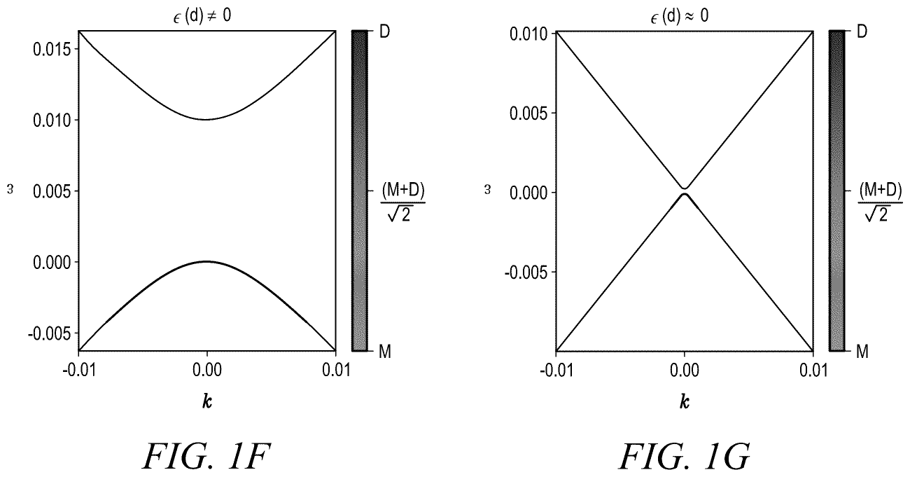

FIG. 1 shows the design of the open-Dirac apertures. As shown in FIG. 1(a), the only requirement to allow for a Dirac degeneracy is a six-fold rotational symmetry in the photonic crystal. Any pattern can be rotated six times by 60° to form a unit cell that can support the required band structure. FIGS. 1b-1e show examples of possible configurations for the unit cell. The design parameter (d) allows control of the detuning (ϵ) between a singly-degenerate monopole-like mode (M) and a doubly-degenerate dipole-like mode (D) of the band structure. Tuning the design parameters such that ϵ approaches 0 causes the bands to mix which induces losses in the higher order modes while the fundamental mode remains pure. FIGS. 1f and 1g show the photonic bands and their purity near the center of the Brillouin zone (FIG. 1f) when d is not tuned close to a degeneracy and when d is tuned to a degeneracy (FIG. 1g).

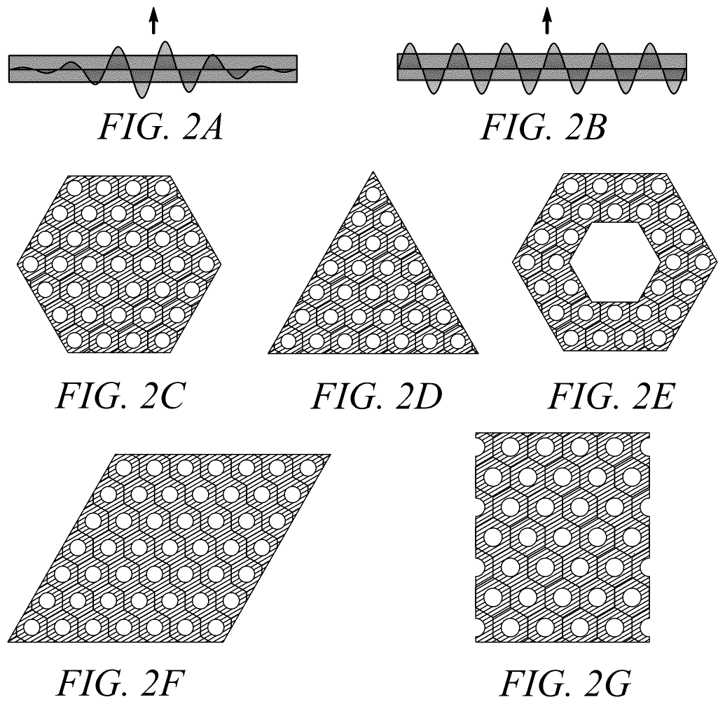

FIG. 2 show examples of truncations that may be used for the Dirac apertures. In particular, FIGS. 2a and 2b show side-views of surface emitting cavities with the electromagnetic mode profile superimposed for conventional apertures (FIG. 2a) and the Dirac aperture (FIG. 2b). As the electromagnetic fields maintain a flat envelope in Dirac apertures, the truncation of the cavity plays an important role in mode selectivity. FIGS. 2c-2g show a top-view of the apertures, demonstrating possible configurations for truncation. Modes with six-fold rotational symmetry can be selected using the configurations in FIG. 2c-2e, while modes with only two-fold symmetry can be selected using the configurations in FIGS. 2f and 2g. Moreover, introducing defects in the cavity as in FIG. 2e can further enhance single-mode operation by favoring the mode with a flat envelope (FIG. 2b), which can “cloak” the defect while conventional modes (FIG. 2a) see increased losses.

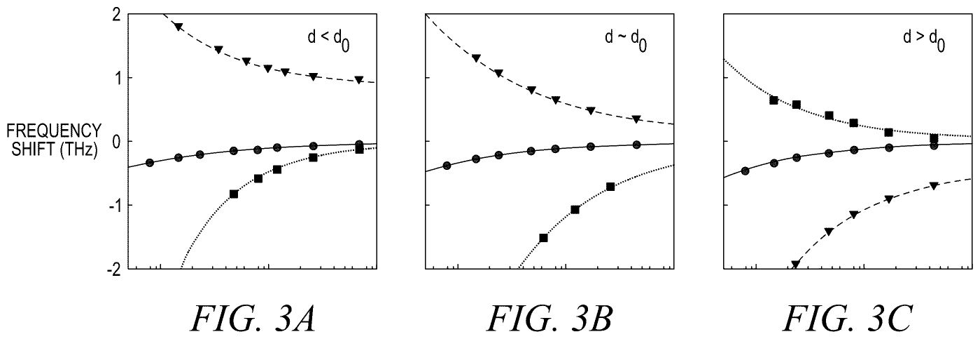

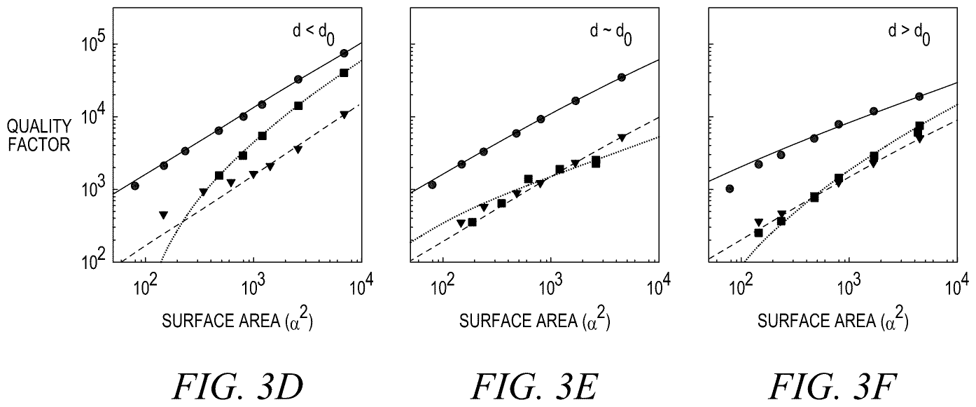

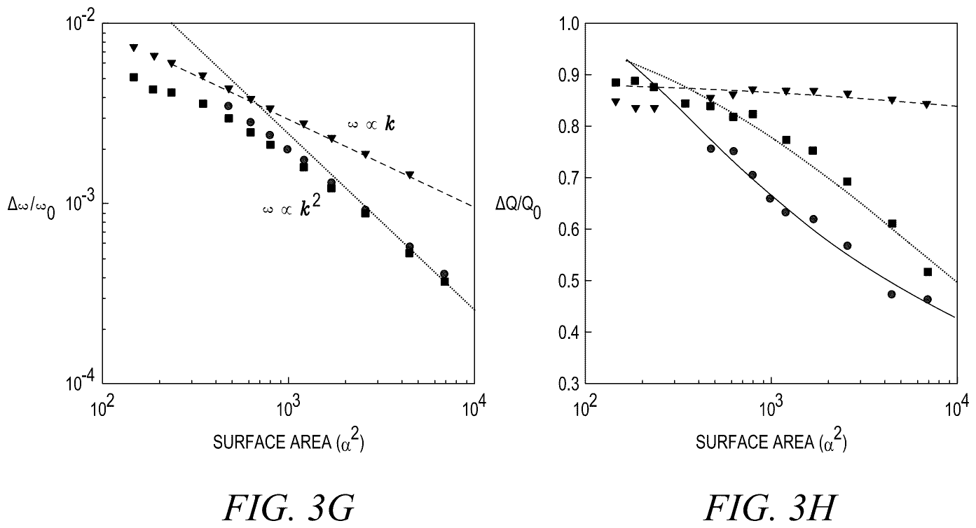

FIG. 3 shows the scaling of frequency and loss rate for the Dirac aperture. FIGS. 3a-3c show that the frequency shift of the cavity modes from the frequency of the monopole-like unit cell mode shown in red, black, blue for design parameter (d) less than, equal to, and greater than d₀ respectively where the detuning ϵ(d₀)=0. The lines are drawn using a theoretical model and the points correspond to data obtained from numerical simulations. The circles on solid lines denote the fundamental cavity mode while the dashed lines with squares and triangle markers denote higher cavity mode 1 (originating from the monopole band) and higher-order cavity mode 2 (originating from the dipole bands) respectively. FIGS. 3d-3f are the same as FIGS. 3a-3c but for the quality factor. FIG. 3g shows the normalized frequency separation between the fundamental cavity mode and the closest higher-order cavity mode. FIG. 3h shows the normalized quality factor difference between the fundamental cavity mode and the cavity mode with the next highest quality factor. Large values indicate a larger threshold for multimode lasing.

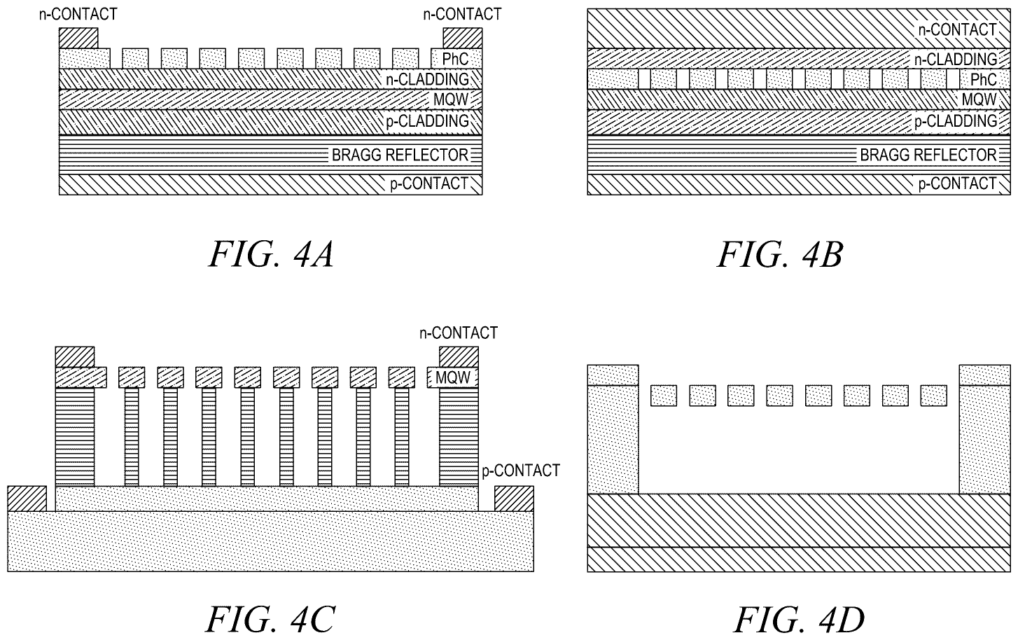

FIGS. 4a-4d show side views of illustrative examples of the scalable surface-emitting layer with the active medium being a multi-quantum well (MQW) in these examples. In the example shown in FIG. 4c conductive pillars are employed to provide electrical contact between the p-contact the photonic crystal. In the example shown in FIG. 4d the photonic crystal is suspended using six bridges (not shown).

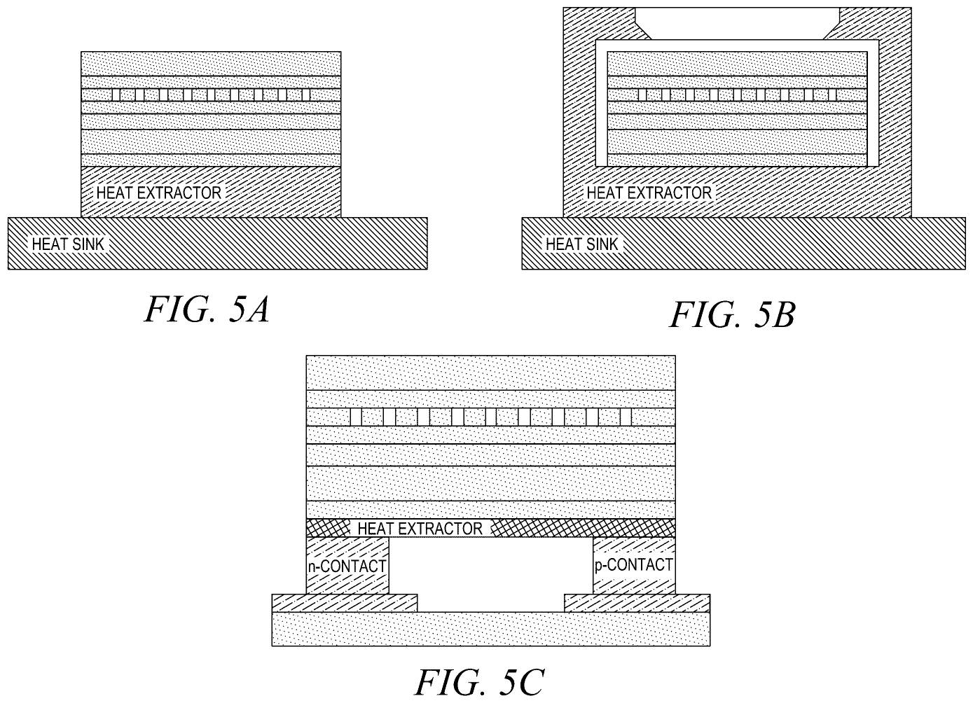

FIGS. 5a-5c show side views of illustrative examples of the scalable surface-emitting layer with various examples of heat extraction schemes using thermos-cooling or substrate cooling.

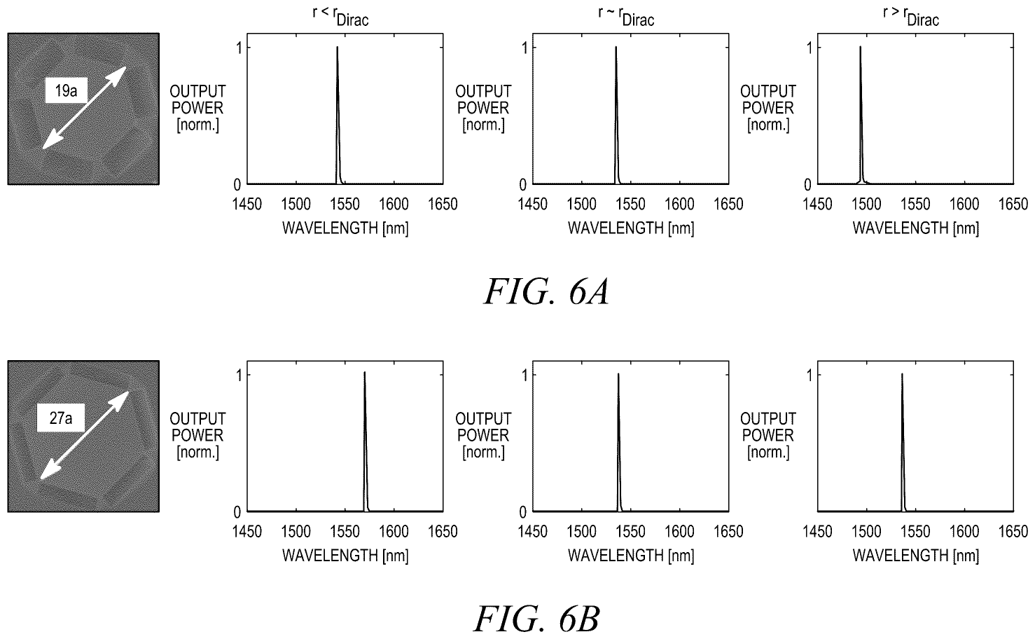

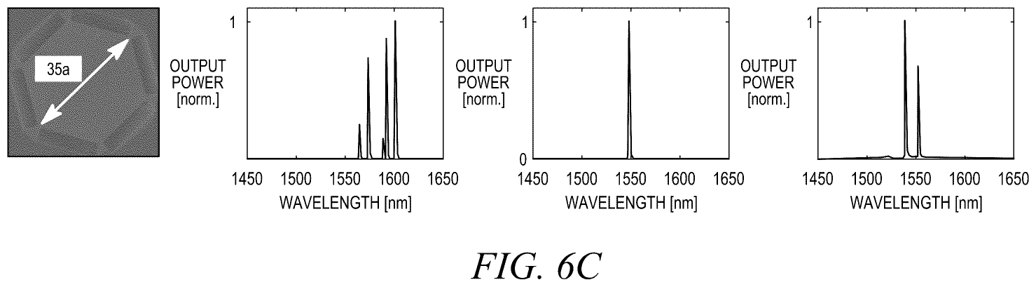

FIGS. 6a-6c show data for fabricated devices with different aperture sizes and the corresponding photoluminescence spectrum and far field. Around the Dirac singularity, the device remains single mode with size scaling. With quadratic dispersion the device becomes multimode with size. For a cavity with length of 19 unit cells (FIGS. 6a) and 27 unit cells (FIG. 6b) all devices demonstrate single mode lasing. This is evidenced from a similar figure of merit shown in FIG. 3(h). However, as shown in FIG. 6d, as the cavity is scaled to a larger size of 35 unit cells, only the Dirac aperture maintains single mode operation

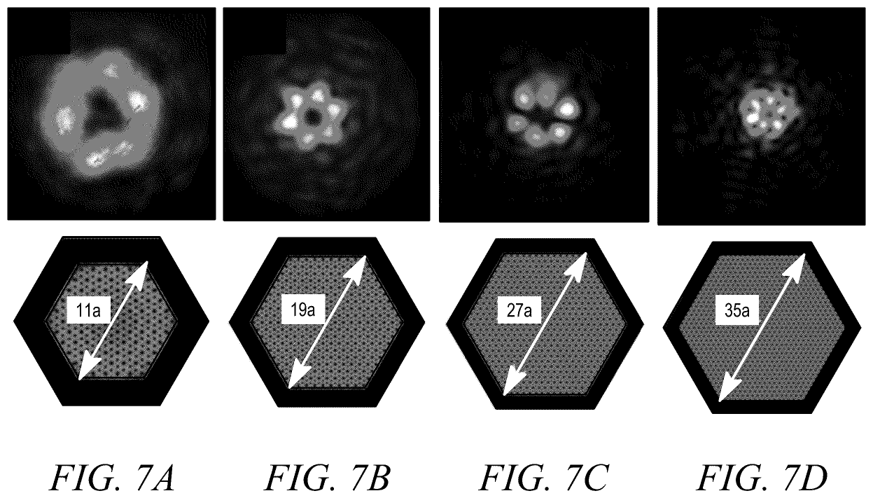

FIGS. 7a-7d show experimental Fourier space images of the laser emission (top) and near field from numerical simulations (bottom) for cavities with a length of 11 unit cells (FIG. 7a), 19 unit cells (FIG. 7b), 27 unit cells (FIGS. 7c), and 35 unit cells (FIG. 7d). Clear six lobes observed in the experiment agree with far-field simulations when the aperture is tuned to the Dirac point. A flat envelope of the near field profiles (bottom) is observed as is expected for mode with linear dispersion. The device lases systematically on the same mode, regardless of the size.

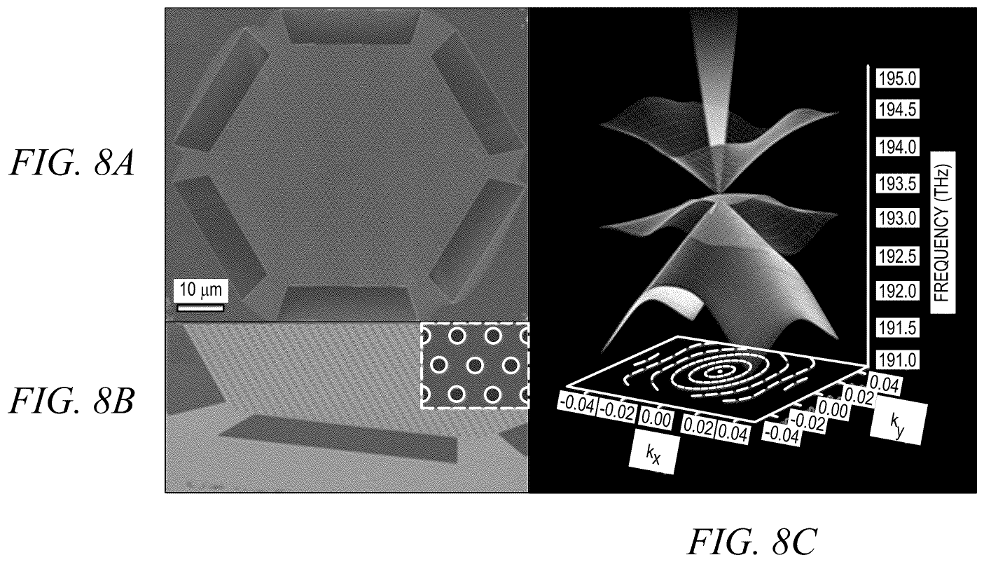

Additional features of open Dirac cavities are shown in FIGS. 8-11, which are described below.

FIGS. 8a-8b show examples of scalable open-Dirac electromagnetic cavities. In particular, FIG. 8a shows a top view scanning electron micrograph of a hexagonal lattice photonic crystal that is truncated to form an open-Dirac electromagnetic cavity. The free-standing structure is suspended via six bridges connecting the main membrane to the substrate along the ΓK direction (Brillouin zone). The cavities are fabricated using electron beam lithography, inductively coupled plasma etching, and wet etching (see the discussion of the device fabrication, below). FIG. 8b shows a titled view of the cavity showing two bridges, the array of holes, and the PhC-air boundary. The thickness of the membrane is 200 nm, the period of the crystal is 1265 nm, and the radius of holes is used to tune cavities around the Dirac singularity. The inset shows the quality of the nanofabrication with near-perfect circular air-holes interfaces. FIG. 8c shows the dispersion of the structure displaying a conical degeneracy at 193.5 THz for holes radii of r_{Dirac}˜273 nm. The lower sheet corresponds to the frequency of the B1-mode and the upper sheets correspond to E2 modes. The truncation of the crystal, that opens the Dirac cone, is notably chosen to be more favorable for the B1-mode compared to the E2-modes, and it serves as an additional selection mechanism to make the cavity single-mode. Also sketched on the dispersion are the iso-frequency contours projected on the (kx, ky) plane together with a representation of laser emission originating from the Dirac point.

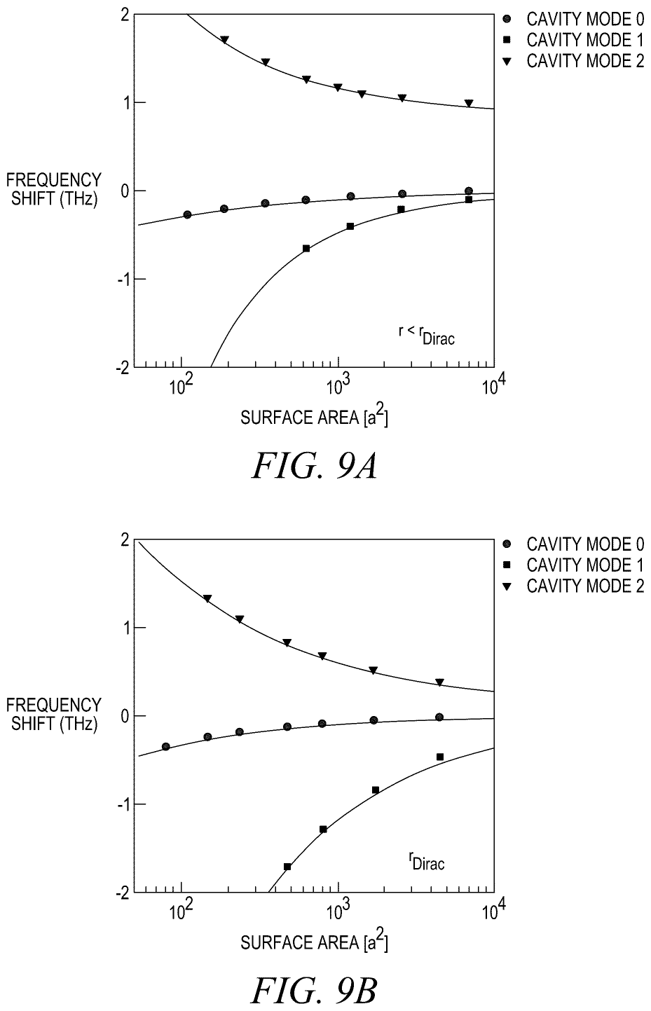

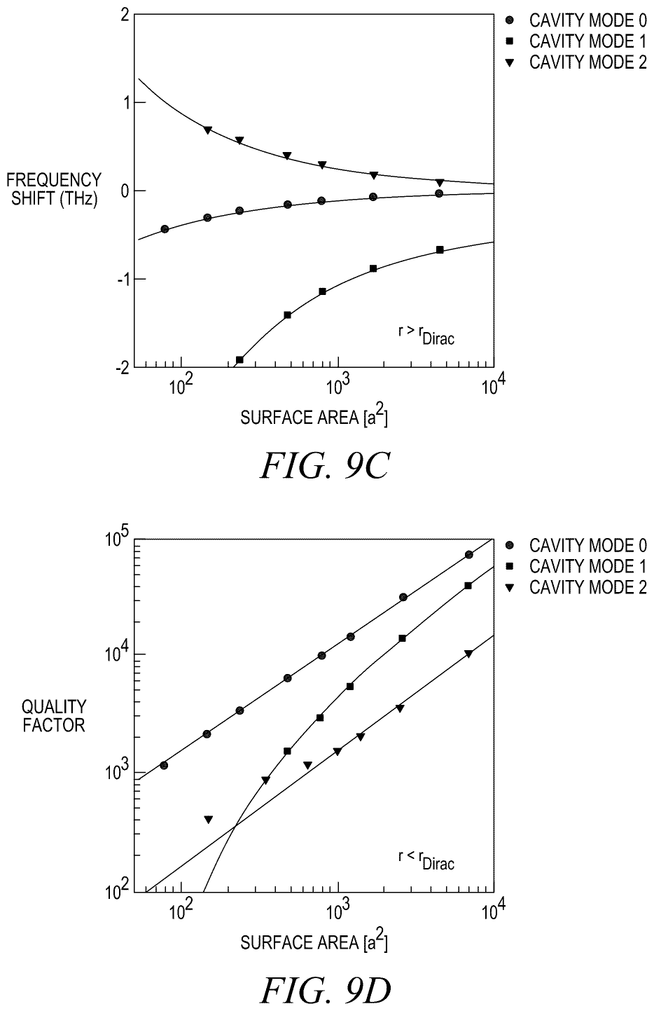

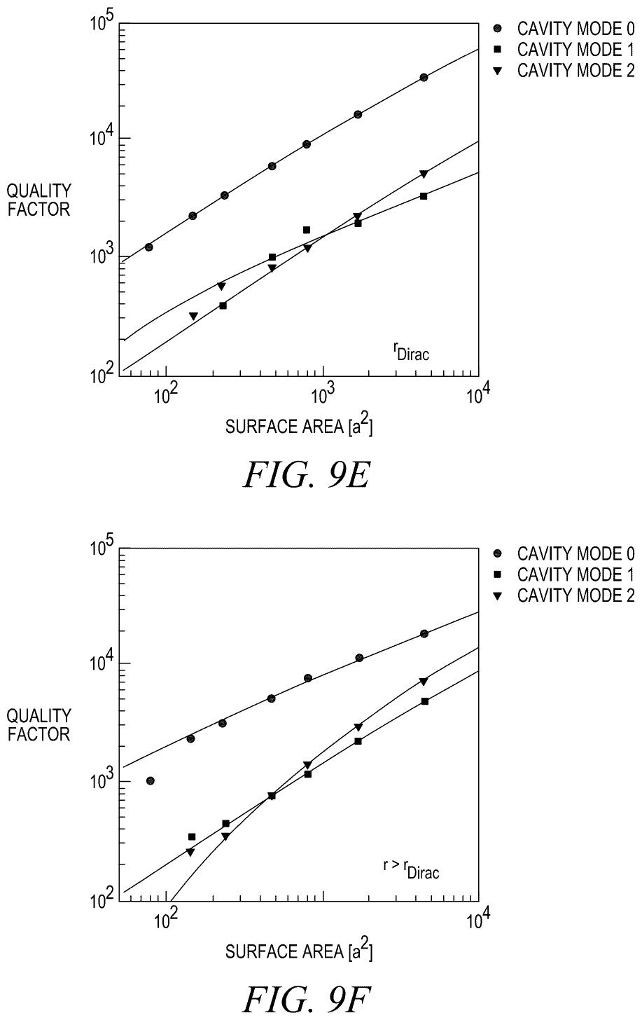

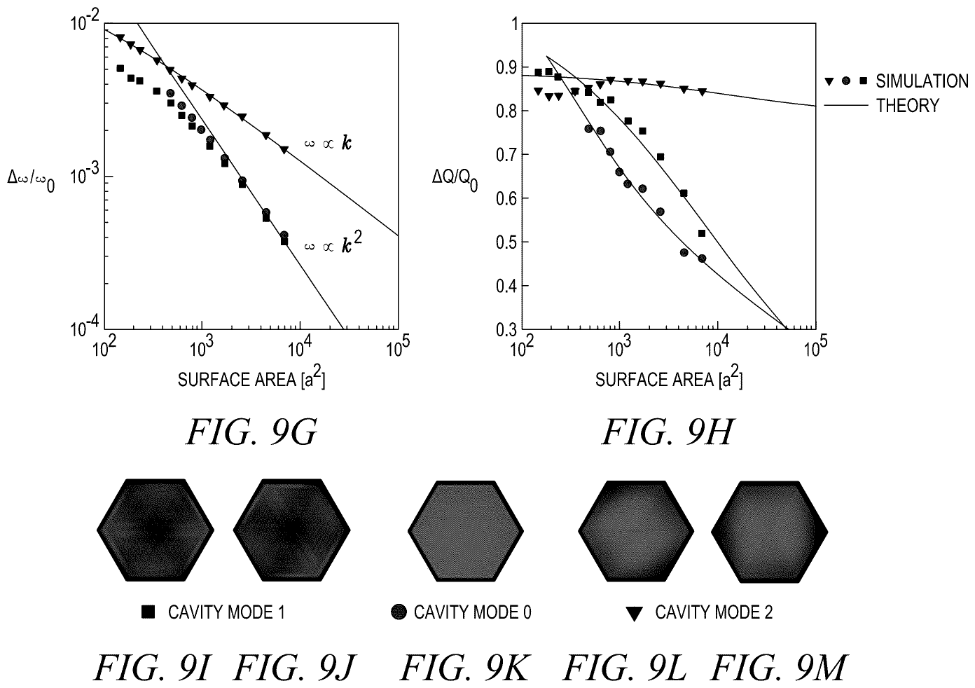

FIGS. 9a-9m illustrate the complex frequency scaling of open-Dirac electromagnetic cavities. Frequency shifts of the first three cavity modes for (FIG. 9a) r<r_{Dirac}, (FIG. 9b) r=r_{Dirac}, (FIG. 9c) r>r_{Dirac}, are computed by comparing cavity modes to the frequency of the B1-mode at the Γ-point for an infinite membrane with holes of the same radius. The quality factor of the first three cavity modes are shown for (FIG. 9d) r<r_{Dirac}, (FIG. 9e) r=r_{Dirac}, (FIG. 9f) r>r_{Dirac}. FIG. 9g shows the scaling of the frequency for various radii. When r is detuned from r_{Dirac}, the dispersion is quadratic, and the frequency shift scales as k². When ris tuned to r_{Dirac} the frequency shift scales as k. FIG. 9h shows the scaling of the quality factor when the radius is detuned from r_{Dirac} and when it is tuned to the singularity. For quadratic dispersion, the cavities have an imaginary free-spectral range that vanishes with the size of cavities. The normalized imaginary free-spectral range does not vanish with the size for our Dirac cavities and can thus be scaled up in size. FIGS. 9i-9j show the degenerate higher-order cavity mode 1, FIG. 9k shows the fundamental cavity mode, and FIG. 9l-9m shows degenerate higher-order cavity mode 2. Interestingly, the fundamental mode has a flat envelope that synchronizes all emitters in the aperture, corresponding to an effective zero-index mode. For all plots, dots are numerical simulations and continuous lines are theory based on our model.

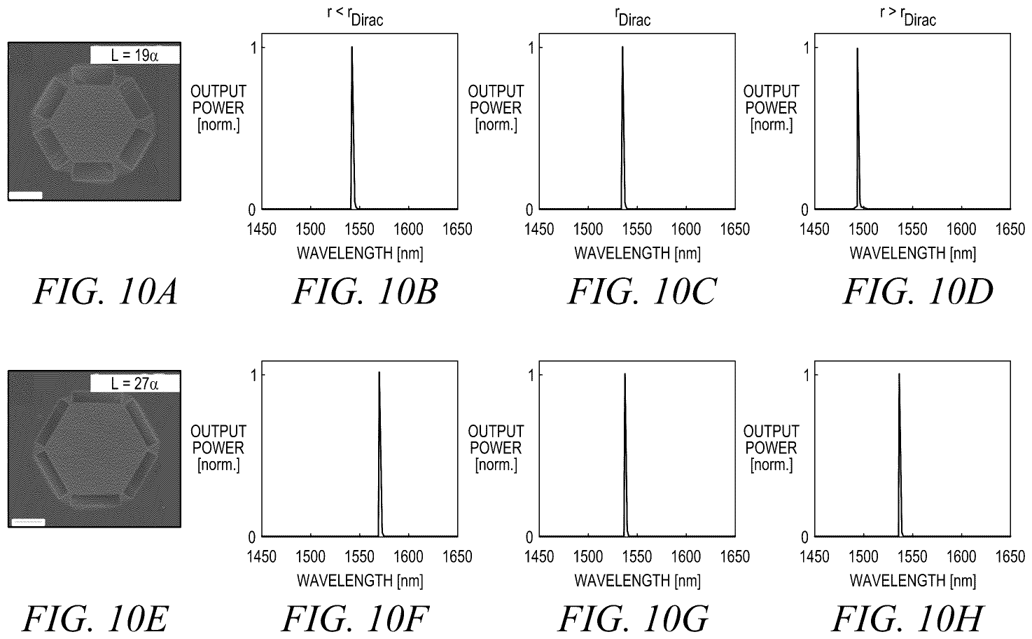

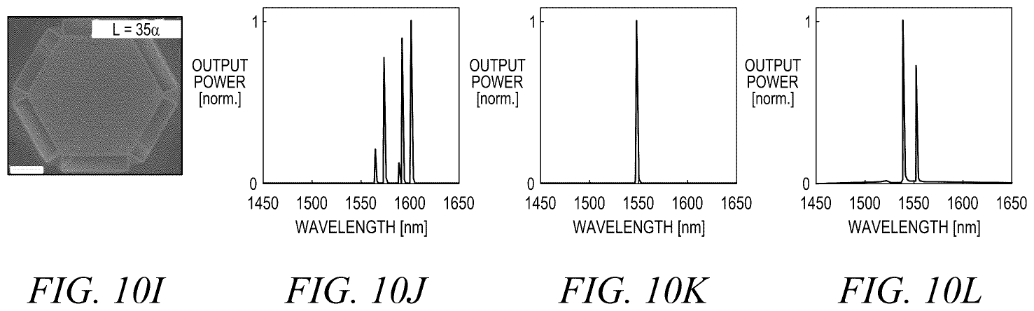

FIGS. 10a-10l illustrate the lasing characteristics of BerkSELs around the Dirac singularity. In particular, the figures show a top-view SEM of fabricated open-Dirac cavities of size L=19a (FIG. 10a), L=27a (FIGS. 10e), and L=35a (FIG. 10i), where a is the size of the unit-cell of the photonic crystal. The evolution of the normalized output power as a function of the wavelength and the size of the cavity is shown for unit-cell holes radii smaller than the singular radius r_{Dirac} (FIGS. 10b, 10f, and 10j, equal to r_{Dirac} (FIGS. 10c, 10g, 10h), and greater than r_{Dirac} (FIG. 10d, 10h, 10l). The pump power density is 1.1 μW/μm² in all cases. For L=19a, cavities are single mode for r<r_{Dirac} (FIG. 10b), r=r_{Dirac} (FIG. 10c), and r>r_{Dirac} (FIG. 10d). For L=27a, cavities are single mode for r<r_{Dirac} (FIG. 10f), r=r_{Dirac} (FIG. 10g), and r>r_{Dirac} (FIG. 10h). When the size is increased to L=35a, we observe that they become multimode mode for r<r_{Dirac} (FIG. 10j), remain single mode for r=r_{Dirac} (FIG. 10g), and become multimode again for r>r_{Dirac} (FIG. 10h). The Dirac singularity erases higher-order modes in open-Dirac cavities and BerkSELs remain single-mode when the size is increased. These experiments validate our theory and make BerkSELs the first scale-invariant surface emitting lasers.

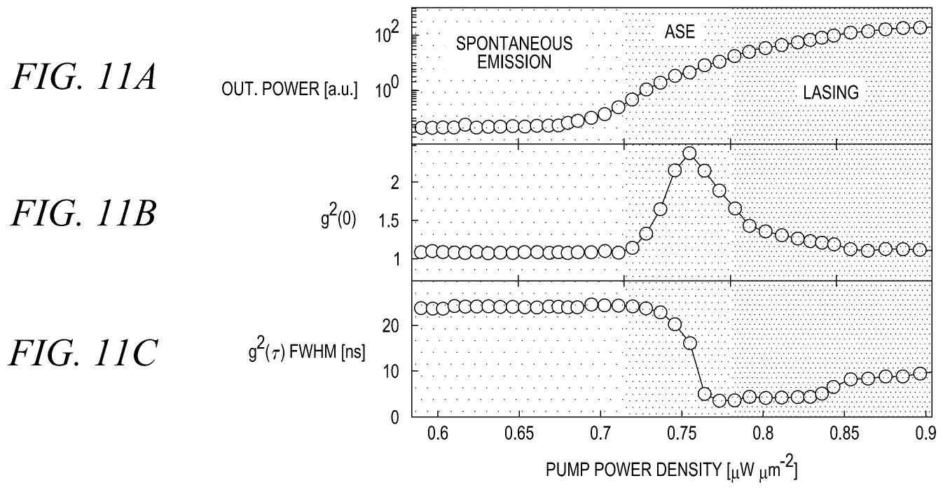

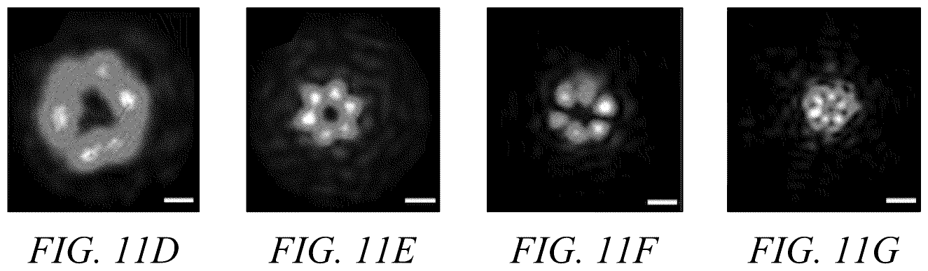

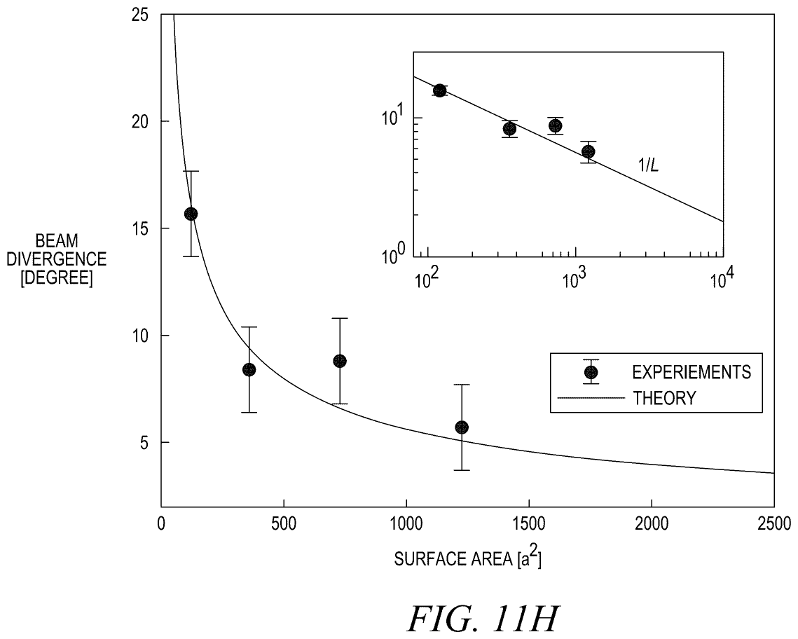

FIGS. 11a-11g show photon statistics and far-field of BerkSELs. In particular, FIG. 11a shows the emitted output power of a BerkSEL of size L=35a (where a is the size of the unit-cell) as a function of the pump power density (light-light curve). FIGS. 11b and 11c show second order intensity autocorrelation measurements at zero delay g²(0) (FIG. 11b) and its pulse width (FIG. 11c). The pulse width of the second-order autocorrelation function shows a distinct transition from spontaneous emission to amplified spontaneous emission (ASE) as the width drops sharply and then from ASE to stimulated emission as the width gradually increases. These transitions unambiguously demonstrate single-mode lasing from BerkSELs. Experimental far-fields (Fourier space images) of BerkSELs under optical pumping are presented for cavity sizes of L=11a (FIG. 11d), L=19a (FIG. 11e), L=27a (FIG. 11f), and L=35a (FIG. 11g). The scale bars indicate 10°. Measured and theoretical beam divergence angle as a function of the cavity size. The continuous line is the theoretical prediction and points are experimental data. A good agreement is observed between theory and experiments. The inset shows the same data plotted in log scale, demonstrating the 1/L scaling of the beam divergence where L is the length of the cavity. This scaling corresponds to the theoretical limit obtained for modes with a flat envelop fully covering an aperture (see FIG. 9k).

### Open Dirac Cavities

A room temperature scalable open-Dirac lasing aperture as described herein exploits the linear dispersion of photons near the band edge of a photonic crystal, and that can be scaled to large sizes. An example of the structure is presented in FIG. 8a. In this example, the structure is a photonic crystal (PhC) with a hexagonal lattice. The unit-cell of the PhC is presented in the inset of FIG. 8b. The linear dispersion of FIG. 8c is obtained with a laterally infinite structure (X-Y direction) by overlapping a doubly degenerate modes of the E2 irreducible representation and a mode from one of the B irreducible representations of the C6v point group (see the theory of lossless Dirac cone formation, discussed below). The degeneracy of the modes at the center of the Brillouin zone is obtained for a critical radius of holes rDirac. An open-Dirac cavity, shown in FIG. 8, is formed by truncating the infinite PhC as a hexagon around a central air-hole with edges normal to the M-directions of the lattice. The entire cavity is suspended in air, and it is connected to the main membrane by six bridges at the corners of the hexagon for mechanical stability (FIG. 8c). The structure is fabricated using electron-beam lithography and the PhC is defined by inductively coupled plasma etching, followed by a wet etching step to create the suspended membrane (see the discussion of device fabrication, below).

To understand the system, we computed modes of open-Dirac cavities of different sizes and for holes radii smaller than, equal to, and greater than the critical radius r_{Dirac}. Note that we only present the first three modes of the cavities as modes of higher order have necessarily a lower quality factor (Q). The computation was performed using a three-dimensional finite-element solver for the transverse electric polarization that corresponds to the polarization providing the highest gain for the multiple quantum wells used in our work. FIGS. 9a-9c (dots) present the computed frequency shifts of the first three cavity modes. The frequency shifts are computed by comparing cavity modes to the frequency of the B1-mode at the Γ-point for an infinite membranewith holes of the same radius. FIGS. 9d-9f (dots) show the scaling of the Q-factor of the same three modes with increasing cavity sizes. When the radius of the holes is not close to r_{Dirac}, Cavity Mode 1 asymptotes to the frequency of the fundamental mode at a rate of k², where k is the wavevector in the cavity. This is shown in FIG. 2g along with the scaling for r_{Dirac} in which case this separation increases to scale as k. Note that Cavity Mode 1 flips from being at a lower frequency than the fundamental mode for r<r_{Dirac} to a greater frequency than the fundamental mode for r>r_{Dirac}. We also observe that even for the cavity with linear dispersion, the frequency separation rapidly drops to about a THz when the length of the aperture along its diagonal reaches L=31a, where a is the size of the unit-cell. The gain spectrum of semiconductors and notably the quantum wells on which the devices were fabricated, spans almost 100 THz, i.e., much larger than real mode spacing. The selectivity of the lasing mode can thus not be enabled by the scaling of the frequency shift afforded by linear dispersion alone as initially claimed.

We now investigate the quality (Q) factor of our Dirac cavities, which have, in this example, a hexagonal truncation. The hexagonal truncation of the cavity can serve as a selector of the fundamental mode shown by circles on solid lines in FIG. 9. The B1-mode has a six-fold rotational symmetry while the E2-modes only have a two-fold rotational symmetry. Thus, the fundamental mode, which is spread out over the entire hexagonal cavity, cannot originate from the E2 bands. Higher-order modes correspond to momentum vectors displaced from the T-point and can have a two-fold rotational symmetry. Hence, these modes may originate from either the B1 band or the E2 band. We will refer to them as Cavity Mode 1 and Cavity Mode 2 and they are denoted by square and triangle markers in FIGS. 9a-9f. FIGS. 9d-9f (dots) show that, as expected, the Q-factor of all the modes increases with the size. We also observe that the Q-factor of the fundamental mode (Q0) decreases as the radius of the air-holes increases. This can be attributed to a decrease in the average refractive index of the membrane, which reduces the confinement of light. Analogous to the scaling of frequency, we observe that the Q-factor of Cavity Mode 1 asymptotes to Q0 when r is detuned from r_{Dirac} [see FIG. 9d (r<r_{Dirac}) and FIG. 9f (r>r_{Dirac})]. Surprisingly, when cavities are tuned to the Dirac point (r=r_{Dirac}) higher-order modes do not asymptote to the fundamental mode anymore as seen in FIG. 9e. They lose energy at a rate always higher than the fundamental mode. Unlike the normalized real-free-spectral range that still decays quickly with the size (FIG. 9g), the normalized imaginary-free-spectral range maintain a non-decaying value despite increasing cavity sizes (FIG. 9h), thus guaranteeing single-mode operation for large apertures.

This unconventional scaling of open-Dirac cavities can be theoretically understood based on the mixing of B and E modes that form the Dirac cone. In our open-Dirac cavities that are a truncation of the infinite structure with no upper limit for the size, the eigenvalue equation can be expressed as,

$$( \begin{matrix}- {σ}_{k} + j {γ}_{B} & 0 & 0 \\ 0 & - {σ}_{k} + j {γ}_{B} & {βδ}_{k} \\ 0 & {βδ}_{k} & ε + {σ}_{k} + j {γ}_{E}\end{matrix} ) ( \begin{matrix}{B}_{1} ( ∞ ) \\ {B}_{1} ( ∞ ) \\ {E}_{2} ( ∞ )\end{matrix} ) = \tilde{ω} ( N ) ( \begin{matrix}\vert 0 > \\ \vert 1 > \\ \vert 2 >\end{matrix} )$$

where the cavity modes |0>, |1>, and |2> are expressed in the basis of the B1 and E2 unit-cell modes of the infinite system. The finiteness of the cavity introduces an uncertainty in the momentum indicated by σₖ˜1/4πN and higher-order modes lie at δₖ=π/N for a cavity with N unit-cells along the diagonal. The loss rates of the modes scale with the size of the cavity as γᵢ=cᵢN⁻¹+dᵢN⁻² (see the discussion of perturbation theory, below), where i=B or E, ci and di are loss rates introduced due to effects of the boundaries. For a large detuning ε of the E2 modes from the B1 modes, the frequency of cavity mode |1> quadratically asymptotes to the frequency of cavity mode |0> and the field profile |1>=e^{jδ}kk/a|0>. The imaginary part of the frequency of cavity mode |1> also rapidly tends to the loss rate of cavity mode |0> and the normalized complex (real and imaginary) free-spectral range thus asymptote to 0. Such cavities are not scale-invariant and become rapidly multimode with the size. However, since the C6 symmetry of the cavity is more favorable for the B modes, we find that d_{E}>d_{B}, and c_{E}>c_{B}. Moreover, when ε→0 the fields in cavity mode |1> are a linear combination of both the B1 and E2 unit-cell modes (FIG. 2i). Hence its loss rate is also defined by the loss rate of cavity mode |2> which originates from the E2 mode, and, for N→∞, the normalized complex free-spectral range tends towards a non-vanishing value of c_{E}/c_{B}˜0.8. Theoretical results, plotted in FIGS. 9a-9h as continuous lines, are in perfect agreement with numerical simulations (dots). Our open-Dirac cavities are thus scale-invariant and remain single-mode when they are scaled-up in size.

To experimentally demonstrate open-Dirac electromagnetic apertures, we characterized fabricated Dirac cavities of sizes L=19a (FIG. 10a), L=27a (FIGS. 10e), and L=35a (FIG. 10i), where a is the size of the unit-cell. The cavities were optically pumped at room temperature with a pulsed laser(λ=1,064 nm, T=12 ns pulse at a repetition rate f=300 kHz) and the emission from each aperture was collected through a confocal microscope optimized for near-infrared spectroscopy (see the discussion of the emission spectra from the BerkSEL at different powers, below). The signal was directed toward a monochromator coupled to a InGaAs photodiode for spectral measurements.

FIG. 10 presents the evolution of the normalized output power as a function of the wavelength and the size of the cavity for unit-cell holes radii smaller than the singular radius r_{Dirac} (FIGS. 10b, 10f, 10j), equal to r_{Dirac} (10c, 10g, 10h), and greater than r_{Dirac} (FIGS. 10d, 10h, 10l). For L=19a, cavities are single-mode for r<r_{Dirac} (FIG. 10b), r=r_{Dirac} (FIG. 10c), and r>r_{Dirac} (FIG. 10d). For L=27a, cavities remain single mode for r<r_{Dirac} (FIG. 10f), r=r_{Dirac} (FIG. 10g), and r>r_{Dirac} (FIG. 10h). This is because these cavities are relatively small. However, when the size of cavities is increased to L=35a or larger, we observe that they become multimode for r<r_{Dirac} (FIG. 10j), remain single mode for r=r_{Dirac} (FIG. 10g), and become multimode for r>r_{Dirac} (FIG. 10h). The Dirac singularity erases higher-order modes in open-Dirac cavities and BerkSELs remain single-mode when the size is increased. It is worth noting that the uniform field profile across the aperture (FIG. 9) for the fundamental mode depletes gain across the aperture, making it even more difficult for higher-order modes to lase. Single-mode lasing is maintained in BerkSELs even for near-damage-threshold pump power. BerkSELs are thus robust to size and pump power density scaling because of the non-vanishing complex free-spectral range and the participation of all resonators to the lasing mode. These experiments validate our theory and make BerkSELs the first scale-invariant surface emitting lasers.

To further characterize the single-mode lasing of BerkSELs, we present in FIG. 11 the light-light curve (FIG. 11a) and the second-order autocorrelation at zero delay g²(τ=0) (FIG. 11b) and its linewidth (FIG. 11c). Three different regimes are observed as the pump power is increased. In the first one at lower pump powers, corresponding to spontaneous emission, the output intensity increase remains negligible and g²(0) is constant. When the pump power is increased, the output power sur-linearly increases, corresponding to amplified spontaneous emission. Photons start to be emitted within one mode of the cavity, leading to a bunching of photons manifested by g²(0)>1. Further increase in the pump power pushes the device beyond the lasing threshold into the regime of stimulated emission at higher pump powers. Coherent light is emitted, evidenced by the decrease of the bunching g²(0) slowly approaching unity. Single-mode lasing action is confirmed by the abrupt decrease of the linewidth of g²(0) near the lasing threshold (FIG. 11c) associated to dynamical hysteresis. To confirm that lasing originates from the theoretically predicted B-mode (see FIG. 2), experimental far-fields (Fourier space images) of BerkSELs under optical pumping are presented for cavity sizes of L=11a (FIG. 11d), L=19a (FIG. 11e), L=27a (FIGS. 11f), and L=35a (FIG. 11g). The six-fold symmetry of the beam (FIGS. 11d-11g) matches well with the far-field obtained from numerical simulations of finite cavities as well as the near-field pattern of the B1 mode of the unit-cell (see the discussion of perturbation theory, below). Scaling up the cavity size manifests in a smaller beam divergence as expected. We plotted the measured beam divergence as a function of the size of the cavity. The measured beam divergence matches with our theory, and it scales as 1/L, where L is the length of the cavity in full agreement with theory for modes with a flat envelop covering the entire aperture.

Additional details concerning the open-Dirac electromagnetic cavities described herein will be presented below.

### Theory Of Lossless Dirac Cone Formation

The formation of Dirac cones at the Γ-point in 2D photonic crystals has been studied extensively by Sakoda (See Sakoda, K. Universality of mode symmetries in creating photonic Dirac cones. J. Opt. Soc. Am. B 29,2770 (2012); Sakoda, K. Proof of the universality of mode symmetries in creating photonic Dirac cones. Opt. Express 20, 25181 (2012)). Sakoda found that an accidental degeneracy between modes belonging to certain irreducible representations of the crystal space group guarantees the formation of lineardispersion Dirac cones. The findings for Photonic crystals (PhCs) with a hexagonal lattice, i.e. the C6v space group, are summarized in Table 1 presented below.

TABLE 1
Dispersion curves obtain near an accidental degeneracy
of modes with different symmetries.

| Mode 1 | Mode 2 | Dispersion curves |
|---|---|---|
| A₁ | B₁ | Q + Q |
| A₁ | B₂ | Q + Q |
| A₁ | E₁ | D + Q |
| A₁ | E₂ | Q + Q + Q |
| A₂ | E₁ | D + Q |
| A₂ | E₂ | Q + Q + Q |
| B₂ | E₁ | Q + Q + Q |
| B₂ | E₂ | D + Q |
| E₁ | E₂ | DD |

D indicates two modes with linear dispersion, Q indicates asingle mode with quadratic dispersion.
Table from Sakoda.

However, Table 1 is only valid for a Hermitian system with no loss and assumes that the PhC is infinite in the direction normal to the periodicity. Moreover, the doubly-degenerate modes with E1 symmetry are dipole-like radiative modes. Hence, when a realistic PhC slab with finite out-of-plane thickness is considered, the eigenfrequencies of the modes are no longer real. For such cases, it has been shown that a Dirac dispersion for radiative modes turns into a square root dispersion if the radiative loss is considered. On the other hand, the single-degenerate A and B modes, as well as the doubly-degenerate E2 mode are non-radiative due to symmetry mismatch with plane waves. Thus, radiative losses do not play a part in a degeneracy involving a A or B mode with an E2 mode and the linear Dirac dispersion can be maintained even when the PhC slab is finite.

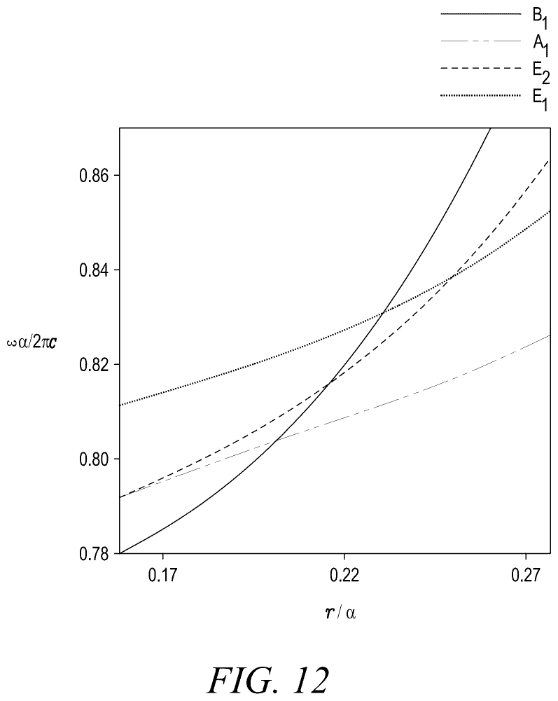

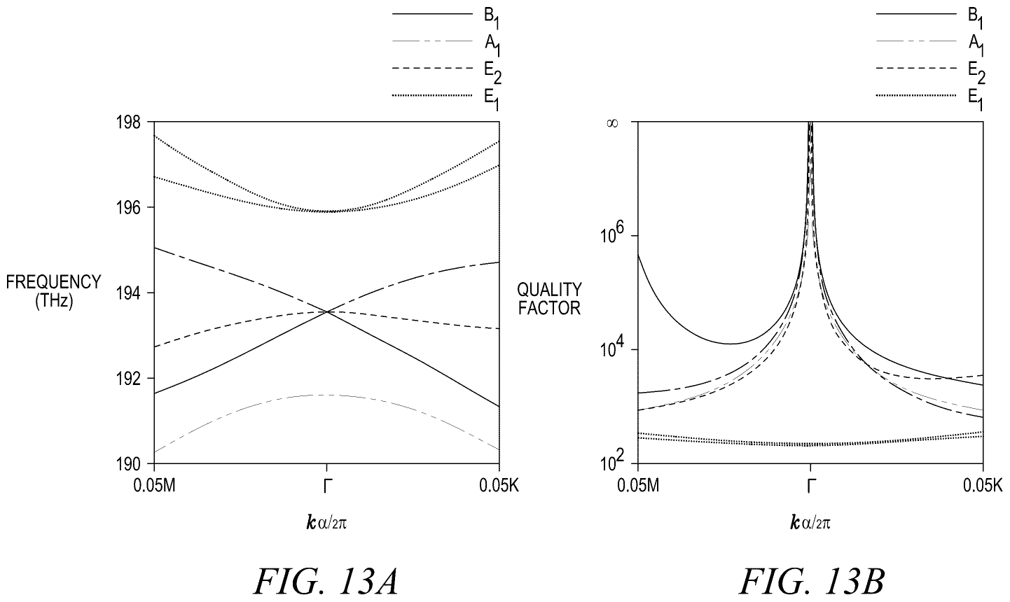

To arrive at the required design, we simulate the unit-cell eigenmodes of an InGaAsP slab with height 200 nm, circular air holes of radius r and a periodicity of a=1376 nm. The frequency dependence of the A1, B1, E1, and E2 modes at the Γ-point is shown in FIG. 12. In FIG. 12, the frequency dependence is shown as a function of the normalized air hole radii r/a, where r is the radius and a the period of the triangular lattice. We find that atr/a≃0.22, the B1 and E2 modes become degenerate. This allows us to maintain linear dispersion even for PhC slabs with a finite thickness and the dispersion as well as quality factor of the final design are shown in FIG. 13. In particular, FIG. 13(a) shows the dispersion of the photonic crystal at the critical radius showing linear dispersion at Γ. FIG. 13(b) shows the corresponding quality factor.

### Perturbation Theory For Infinite System

The coupling matrix between the B1 and E2 modes can be expressed as:

$${C}_{k} = ( \begin{matrix}0 & 0 & {bk}_{y} \\ 0 & 0 & - {bk}_{x} \\ {b}^{*} {k}_{y} & - {b}^{*} {k}_{x} & 0\end{matrix} ) , \qquad ( 1 )$$

where b is the overlap integral between the Bloch modes. Since only two of the three modes arecoupled along one direction of the k-vector, this 3×3 matrix can be reduced to a 2×2 matrix.

Next, we consider the rate of radiation induced by some non-zero k near the Γ-point. For symmetry-protected bound states in the continuum, the radiation rate is dependent on the topological charge. The topological charge or winding number for the B₁ mode and the two E₂ modes is q=−2. For the non-degenerate B₁ mode, this means that the loss rate scales as k⁴, while for the doubly degenerate E₂ modes the loss rate scales as k². If the detuning between the B₁ and E₂ modes is ϵ, we can now write the reduced non-Hermitian eigenvalue equation as:

$$( \begin{matrix}{jk}^{4} & β k \\ β k & ϵ + {jk}^{2}\end{matrix} ) ( \begin{matrix}{B}_{1} ( Γ ) \\ {E}_{2} ( Γ )\end{matrix} ) = \tilde{ω} ( k ) ( \begin{matrix}{B}_{1} ( k ) \\ {E}_{2} ( k )\end{matrix} ) , \qquad ( 2 )$$

where j is the imaginary number, β the group velocity. Solving the eigenvalues of this equation yields the dispersion curves \tilde{ω}(k) as well as loss rates for the modes forming the Dirac cone in an infinitely periodic system. The above equation also implies that there is mixing between the modes as we move away from the Γ-point. The eigenvectors of the system at some finite k valuesare:

$${B}_{1} ( k ) = {aB}_{1} ( Γ ) + {bE}_{2} ( Γ ) , \qquad ( 3 )$$

$${E}_{2} ( k ) = {bB}_{1} ( Γ ) - {aE}_{2} ( Γ ) , \qquad ( 4 )$$

$$\vert {a}^{2} \vert + \vert {b}^{2} \vert = 1. \qquad ( 5 )$$

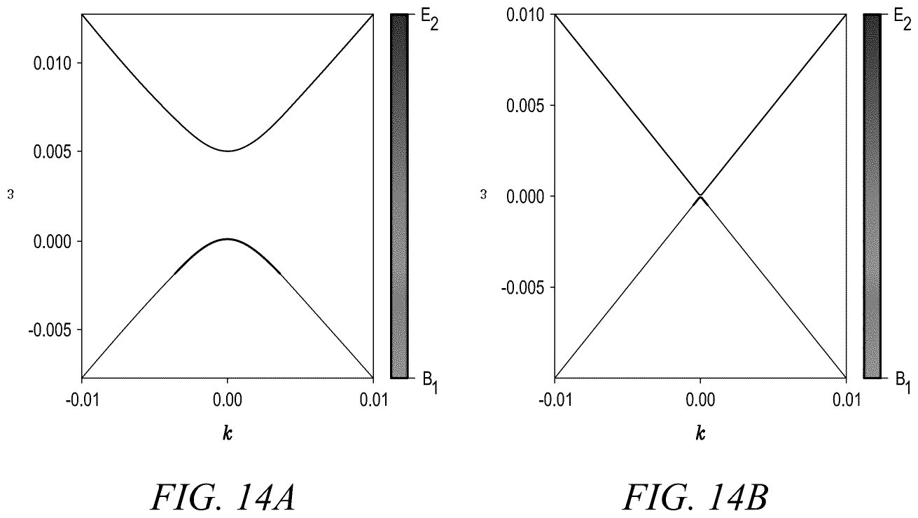

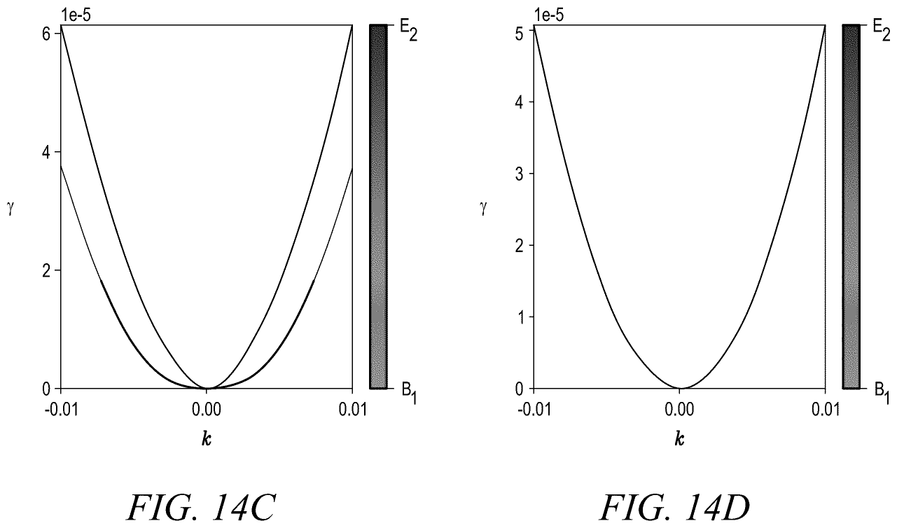

FIG. 14 shows the dispersion of the real and imaginary part of the eigenvalues for the two degenerate modes B₁ and E₂. The data demonstrate the mixing of the modes. The dispersion of the real part is shown in FIGS. 14(a) and 14(c). We clearly observe that the quadratic band edge in FIG. 14(a) for ϵ≠0 turns linear in 14(c) for ϵ≈0.

For the imaginary part, we observe a clear distinction between the quartic and quadratic scalingof the B1 and E2 modes when ϵ≠0 (FIG. 14b). Quartic scaling is not favorable for a single mode laser because the higher order modes which are shifted from the Γ-point also have a low loss rate which is comparable to the loss rate of the fundamental mode. However, the mixing between the modes when ϵ≈0 also induces greater losses in the B1 mode as we move away from the Γ-point (FIG. 14d).

### Perturbation Theory For Finite Systems

In the section above, we derived the dispersion of the complex frequency for an infinite system. To include the effects of finiteness and boundaries of the cavity, we introduce additional loss terms as well as uncertainties in the momentum that arise from the Fourier transform of a bounded function. Furthermore, we consider the splitting of Bloch bands into discrete modes. Three cavity modes with frequencies nearest to the unit cell frequency of the B1 mode at the Γ-point are considered since the quality factor of the higher order modes is in general less than the lower order modes. In the absence of any loss Equation (2) can be updated to reflect these changes as follows,

$$( \begin{matrix}- {σ}_{k} & 0 & 0 \\ 0 & - {σ}_{k} & {βδ}_{k} \\ 0 & {βδ}_{k} & ϵ + {σ}_{k}\end{matrix} ) ( \begin{matrix}{B}_{1} ( ∞ ) \\ {B}_{1} ( ∞ ) \\ {E}_{2} ( ∞ )\end{matrix} ) = \tilde{ω} ( L ) ( \begin{matrix}\vert 0 〉 \\ \vert 1 〉 \\ \vert 2 〉\end{matrix} ) , \qquad ( 6 )$$

where, σₖσₓ≥ [symbol] and δₖ∝L̅. Here σₖ is the uncertainty in momentum, σₓ is the uncertainty in the position which is proportional to the size of the cavity L, and δₖ is the momentum of the firsthigher order mode. The initial uncoupled states are the Bloch modes at the Γ-point, corresponding to an infinite cavity, and are denoted by B₁(∞) and E₂(∞). The finiteness of the cavity induces a coupling between the higher order B and E modes because as seen in the previous section, the modes are uncoupled at the Γ-point but mix when the in-plane momentum is non-zero. The cavity modes thus obtained are denoted by |0 [symbol] , |1 [symbol] and |2 [symbol] . Solving the eigenvalue equation yields to the frequency of the three lowest order modes of the finite Dirac cavity.
Next, we introduce terms responsible for energy loss from the cavity. The quality of a photonic crystal cavity can be expressed as,

$$Q = \frac{Energy stored}{Energy lost} = \frac{{L}^{2}}{cL + d} . \qquad ( 7 )$$

The loss rate from the cavity edges is proportional to the length of the cavity L, the energy stored is proportional to the surface area of the cavity L² and the corners introduce additional loss which does not scale with the size of the cavity. Thus, we can express the imaginary part of frequency as,

$$γ ∝ \frac{1}{Q} = \frac{c}{L} + \frac{d}{{L}^{2}} . \qquad ( 8 )$$

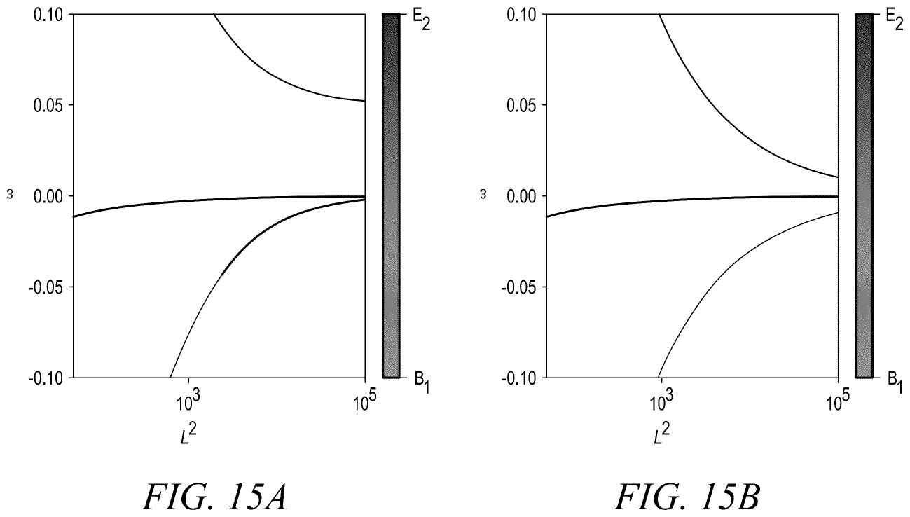

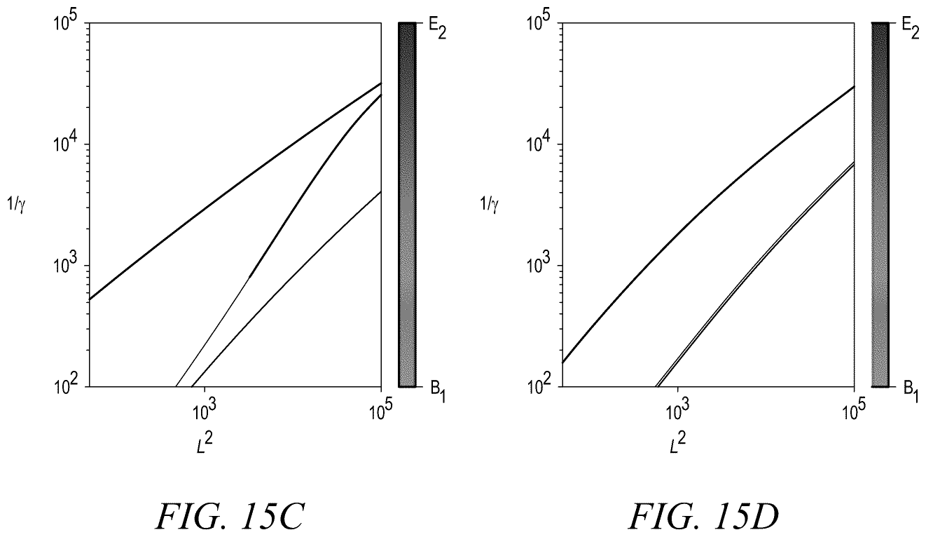

The final eigenvalue equation is then,

$$( \begin{matrix}- {σ}_{k} + j {γ}_{B} & 0 & 0 \\ 0 & - {σ}_{k} + j {γ}_{B} & {βδ}_{k} \\ 0 & {βδ}_{k} & ϵ + {σ}_{k} + j {γ}_{E}\end{matrix} ) ( \begin{matrix}{B}_{1} ( ∞ ) \\ {B}_{1} ( ∞ ) \\ {E}_{2} ( ∞ )\end{matrix} ) = \tilde{ω} ( L ) ( \begin{matrix}\vert 0 〉 \\ \vert 1 〉 \\ \vert 2 〉\end{matrix} ) , \qquad ( 9 )$$

where the loss rates γ_{B} and γ_{E} for the B and E modes respectively are obtained by curve-fitting the full-wave 3D numerical simulations. The scaling of the frequency and inverse of the complex frequency for the three modes are shown in FIG. 15. The same theory was used to plot the theoretical curve for FIG. 2.

### Device Fabrication

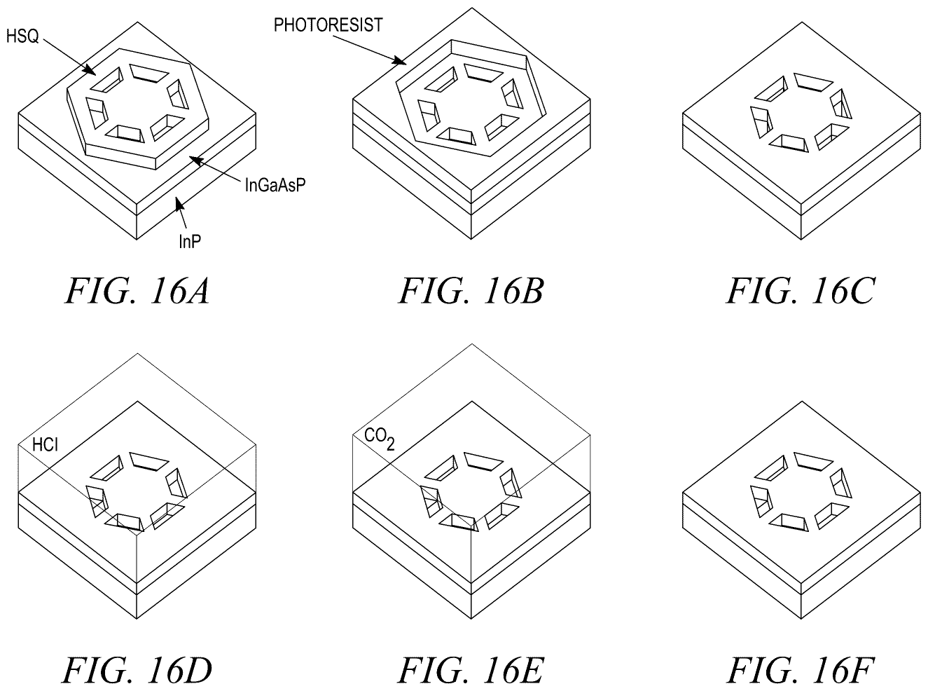

The flowchart of the nanofabrication process is illustrated in FIG. 16. The photonic crystal cavity is prepared on InGaAsP multiple quantum wells (MQWs) with a gain spectrum over telecommunication wavelengths. After the InP capping layer is removed, the InGaAsP wafer is cleaned by typical acetone and isopropyl alcohol ultrasonication. Subsequently, hydrogen silsesquioxane (HSQ) negative tone resist is spin-coated on the wafer and the Dirac photonic crystal is patterned by electron-beam lithography (FIG. 16a). To avoid unwanted wet etching of the InP sacrificial layer, we added photolithography (FIG. 16b). In the following step, induced coupled plasma (ICP) dry etching with a mixture of H2, CH4, Ar, and Cl2 gas is performed to transfer the patterns to the InGaAsP slab. Then the HSQ layer is removed by a buffered oxideetchant (BOE) solution (FIG. 16c). The device is suspended by a diluted HCl (3:1) solution which selectively removes the InP sacrificial layer under the InGaAsP (FIG. 16d). To avoid stiction issues induced by the capillary force when drying the sample, we introduced the critical point drying (CPD) technique (FIG. 16e). The sample is finalized after supercritical phase carbon dioxide drying (FIG. 16f).

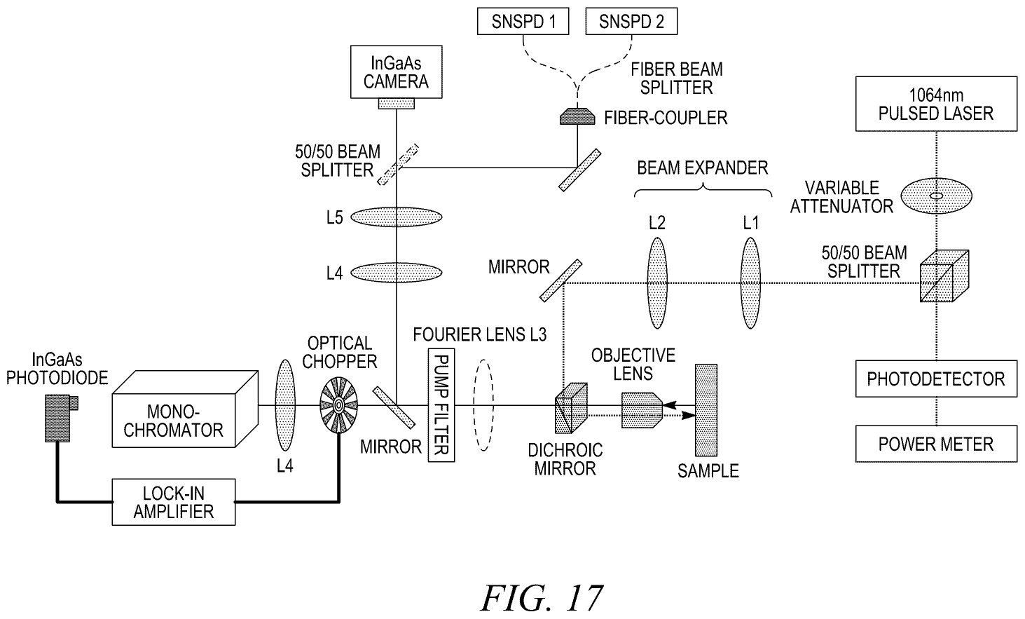

The fabricated devices are characterized by photoluminescence (PL) measurements. The PL arrangement is presented in FIG. 17. The sample is optically pumped from the top side with a 1064 nm pulsed laser (12 ns of pulse width and repetition rate of 300 kHz). A 20× long working distance microscope objective (NA of 0.4) focuses the pump beam on the sample and collects the lasing emission simultaneously. The pump beam size is adjusted by a telescope (lenses L1 and L2) tuning the divergence of the beam. The pump power is finely tuned by an optical attenuator and monitored by a power meter. PL signals are captured by an IR-CCD (FLIR InGaAs) and a monochromator (HRS-750 Princeton instruments). The spectrum is obtained in conjunction with a cooled InGaAs detector in lock-in detection configuration. To get a Fourier image of the aperture we need to image the back focal plane of the objective lens. We set a Fourier lens behind the objective lens such that the back focal plane is sent to infinity. The image is then relayed through lenses L4 and L5 and the image is then focused (L6) onto an InGaAs camera. For autocorrelation measurements we used an Hanbury-brown and Twiss interferometer consisting of a fiber-coupler to direct the signal into a fiber beam splitter. Each end of the beam splitter is connected to two superconducting nanowire single photon detectors (ID230 with 2 ns dead time and 100 ps timing jitter). The coincidence histogram is recorded via a time controller (ID900).

### Emission Spectrum from the BerkSEL at Different Powers

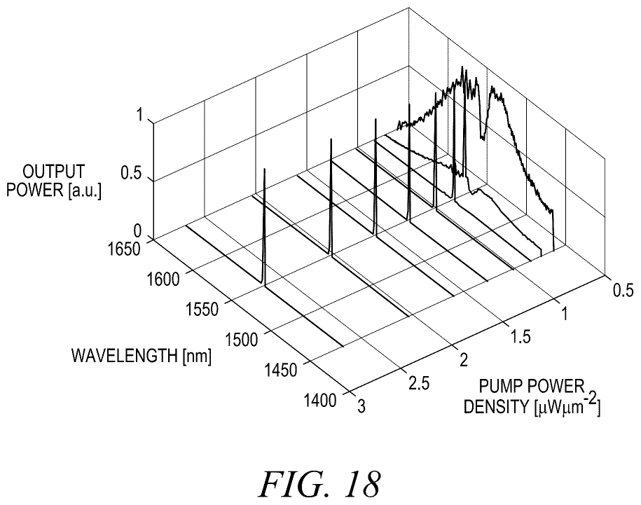

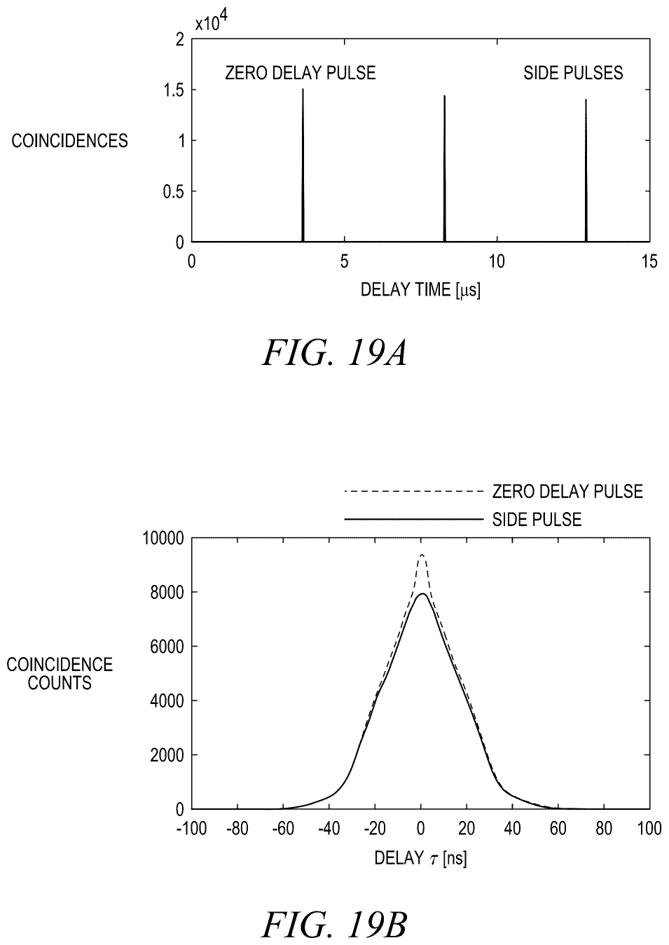

We also characterized our devices by measuring the second-order intensity correlation function

$${g}^{2} ( τ ) = \frac{I ( t ) I ( t + τ )}{2} ,$$

where [symbol] I(t) [symbol] represents the expectation value of the intensity at time t, with [symbol]
I(t) [symbol]
a Hanbury Brown-Twiss (HBT) interferometer (FIG. 17). FIG. 18 shows the emission spectra from the BerkSEL (L=35a). Single mode is maintained up to 3 μW μm² corresponding to the power where the suspended membrane starts to be damaged.
FIG. 19(a) presents an example of the experimental coincidence histogram showing several peaks separated by 4.6 μs, which corresponds to the inverse of the repetition rate of our pump laser (215 kHz). In FIG. 19(b) we show a zoomed view on the zero-delay pulse superimposedwith a side pulse. The pulse width at half maximum is 24 ns that is exactly twice the pump laser pulse width.

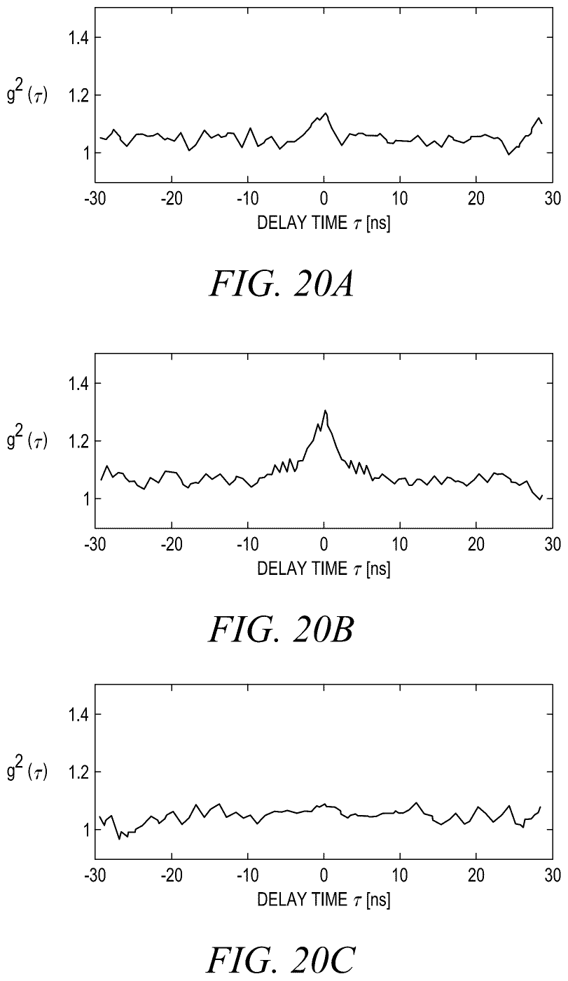

To extract the normalized autocorrelation function, we divide the zero-delay pulse by the average of the side pulses. We present in FIGS. 20(a), 20(b) and 20(c) g²(τ) for three different pump power, below threshold (0.7 μW μm²) at the threshold (0.76 μW μm²) and after threshold (0.8 μW μm²) respectively. g²(0) and its linewidth are shown in FIG. 4(a) or extracted from FIG. 20.

In summary, scale-invariant cavities have been demonstrated that maintain single-mode when the size of the cavity is increased. These open-Dirac electromagnetic cavities are robust against size scaling. The unique scaling stems from a complex free-spectral range that does not vanish with the size of cavities. Around the Dirac singularity, an admixture of higher-order modes with morelossy band of the structures effectively suppresses those modes. The fundamental mode of the cavity has a flat envelop that makes all resonators in the aperture participate in the mode. The fundamental mode thus effectively locks all unit-cells (or resonators) in the aperture in phase, a long-standing challenge. Lasers based on such cavities are surface emitting apertures that we named Berkeley Surface Emitting Lasers (BerkSELs). We have confirmed single-mode lasing from BerkSELs by measuring their second order intensity correlation. We have further confirmed the lasing mode by measuring far-field emissions that agree with our theory. These results demonstrate the fundamental importance of openness for enabling scaling in optics, and, they can have implications in linear and non-linear classical and quantum wave-based systems such as electronics, acoustic, phononic, or photonics based on real or synthetic dimensions. The simplicity of BerkSELs makes them universal apertures, readily relevant to applications including virtual reality systems, lidars, interconnects, manufacturing, or lasers for imaging and medicine.

Various exemplary embodiments of the present surface-emitting, single mode laser are now presented by way of illustration and not as an exhaustive list of all embodiments. An example includes a surface-emitting, single mode laser having a gain medium and a photonic structure. The gain medium is configured to emit an electromagnetic wave. The photonic structure is electromagnetically coupled to the gain medium and has a cavity mode-dependent scaling of losses so that higher order modes are coupled to more lossy bands and a fundamental mode, at a high symmetry point, is coupled to a less lossy band of the photonic structure. In another example the photonic structure is implemented using a photonic crystal. In another example the cavity mode-dependent scaling of losses is enabled by a simultaneous implementation of an open-Dirac cone and truncations forming boundaries of the photonic structure. In another example the gain medium comprises at least one of a quantum well, a quantum dot, a quantum wire, and an organic molecule. In another example the gain medium comprises at least one of GaAs, AlGaAs, InGaAs, InGaAsP, GaN, Si, Ge, GaP, InAlGaN, InAs, InSb and SiN. In another example the photonic structure supports propagation of a single mode of the electromagnetic wave in a plane of the photonic crystal. In another example the single mode is a first mode from a center of a Brillouin zone of the photonic structure. In another example a mode spacing between consecutive cavity modes is a complex number. In another example the photonic crystal includes an aperture and the real part of the mode spacing scale as 1/N with a linear dispersion, where N is a size of the aperture or a number of unit-cells across a diagonal of the aperture such that for a unit-cell of length a, the aperture has a diagonal of size Na. In another example an imaginary part of the mode spacing scales as γᵢ=cᵢN⁻¹+dᵢN⁻² where “i” is a mode number and c₂>c₁, thereby making higher order modes more lossy than the fundamental mode. In another example all modes are symmetry protected modes with high quality factors but truncation dependent scaling. In another example cᵢ are controlled by a symmetry of the photonic structure and its truncation. In another example N is between 5 for smaller aperture to N=1 million for larger apertures. In another example an open-Dirac dispersion is tuned from quadratic to linear by overlapping at least two modes of different symmetries. In another example the truncations of the crystal are arranged to be more favorable to one of the modes and less favorable to another of the modes. In another example the truncations of the crystal are arranged to match a symmetry of the fundamental mode at a unit-cell level. In another example the aperture with N elements along its diagonal defines an area that couples energy out of the surface-emitting, single mode laser for lasing. In another example a unit-cell of the photonic structure is arranged so that an infinite structure exhibits a Dirac point involving at least two bands by overlapping symmetry-protected modes that have different symmetries. In another example the photonic crystal has at least two refractive index n₁ and n₂, a period and a pattern, where a pattern geometry is modified so that dispersion is tuned to linear. In another example the pattern is modified so that it has six-fold symmetry. In another example the pattern is circular. In another example the Dirac point induces mixing between the two bands away from the high symmetry point to thereby add loss to higher order modes originating from the less lossy band. In another example the photonic crystal defines a plurality of holes of any shape having a rotational symmetry that is the same as the lattice and a refractive index different from a refractive index of the lattice. In another example the photonic crystal defines a plurality of rods of any shape having a rotational symmetry that is the same as the lattice and a refractive index different from a refractive index of a surrounding environment. In another example the holes or rods are arranged in at least one of an oblique lattice, a rectangular lattice, a rhombic lattice, a square lattice, or a hexagonal lattice. In another example the period a is about 50 nm to 5 mm and the electromagnetic wave has a wavelength λ and the photonic structure has a thickness of λ/20 to 20 λ. In another example the surface-emitting, single mode laser further includes at least one electrode in contact with the photonic structure and the gain medium to inject current laterally and stimulate emission of the electromagnetic wave. In another example at least one electrode is in contact with conductive materials to vertically inject current in the photonic structure and the gain medium and stimulate emission of the electromagnetic wave. In another example the method further includes packaging for the gain medium and the photonic structure, the packaging including a heat extraction layer. In another example the packaging is configured for optical pumping of the gain medium. In another example the packaging is configured for electrical pumping of the gain medium. In another example a metallization layer for electrical injection are selected from a group of materials including gold, gold alloys, platinum, nickel, and nickel alloys. In another example a cooling arrangement is provided that includes a plurality of non-conductive materials having a thermal conductivity that extracts heat from the surface-emitting, single mode laser. In another example the high symmetry point is a center of a Brillouin zone.

A further example includes a method of making a surface-emitting, single mode laser. In accordance with the method, a photonic crystal is fabricated with a complex band structure characterized by an open-Dirac point at a center of a Brillouin zone and higher order modes offset from a center of the Brillouin zone with higher losses enabled by coupling to a more lossy band of the photonic crystal. A gain medium is disposed in electromagnetic communication with the photonic crystal having an energy band structure characterized with an open-Dirac point at a frequency within the gain bandwidth of the gain materials so as to support propagation of a single mode in the photonic crystal and radiation of electromagnetic energy out of plane.

In another example the single mode is at a high symmetry point of a Brillouin zone of the photonic crystal. In another example fabricating the photonic crystal includes defines a truncated photonic crystal cavity with at least one dimension having a length of Na where a is the size of the unit-cell that defines a two-dimensional area proportional to N² and a spacing between a first mode and a closest higher order modes scales as N⁻¹. In another example fabricating the photonic crystal includes defining a truncated photonic crystal cavity with at least one dimension having a length of N that defines a two-dimensional area proportional to N² and a spacing between a first mode and a closest higher order mode scales as N⁻¹. In another example fabricating the photonic crystal includes defining a truncated photonic crystal cavity such that a loss rate of higher order modes has a constant ratio invariant of N. In another example fabricating the photonic crystal includes selecting at least one of hole size, hole shape, rod size, rod shape, hole pitch, rod pitch, thickness, refractive index, period of the photonic crystal so as to form a degeneracy at the open-Dirac point of at least two energy bands of the photonic crystal. In another example fabricating the photonic crystal includes choosing the shape of the truncated cavity such that a loss rate of at least one of the energy bands is smaller than the other energy bands involved in formation of the open-Dirac point. In another example fabricating the photonic crystal includes defining a plurality of holes of any shape with the same rotational symmetry as the lattice and a refractive index different from a refractive index of the lattice. In another example fabricating the photonic crystal defines a plurality of rods of any shape with a rotational symmetry that is the same as a lattice of the photonic crystal and a refractive index different from the refractive index of the surrounding environment. In another example fabricating the photonic crystal defines holes or rods arranged in at least one of an oblique lattice, a rectangular lattice, a rhombic lattice, a square lattice, or a hexagonal lattice. In another example fabricating the photonic crystal includes selecting a period of the photonic crystal to be about 50 nm to about 50 cm. In another example the electromagnetic wave has a wavelength λ and fabricating the photonic crystal includes selecting a thickness from λ/20 to 20 λ. In another example fabricating the photonic crystal includes etching at least one of GaAs, AlGaAs, InGaAs, InGaAsP, GaN, Si, Ge, GaP, InAlGaN, InAs, InSb, SiO₂ and SiN. In another example fabricating the photonic crystal includes depositing at least one electrode to be in contact with the photonic crystal and gain medium for injecting current laterally and stimulate emission of the electromagnetic wave. In another example fabricating the photonic crystal includes forming conductive pillars under at least one unit cell and depositing at least one electrode in contact with the pillars for injecting current in the photonic crystal and the gain medium and stimulate emission of the electromagnetic wave. In another example fabricating the photonic crystal includes depositing at least one electrode in contact with conductive materials to vertically inject current in the photonic crystal and gain medium and stimulate emission of the electromagnetic wave. In another example fabricating the photonic crystal includes placing at least one electrode in contact with a power source. In another example fabricating the photonic crystal includes selecting a gain medium that includes at least one of a quantum well, a quantum dot, a quantum wire, or organic molecule. In another example fabricating the photonic crystal includes selecting a gain medium comprising at least one of GaAs, AlGaAs, InGaAs, InGaAsP, GaN, Si, Ge, GaP, InAlGaN, InAs, InSb, SiO₂ and SiN.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. A surface-emitting, single mode laser, comprising:
a gain medium configured to emit an electromagnetic wave; and
a photonic structure electromagnetically coupled to the gain medium and having a cavity mode-dependent scaling of losses so that higher order modes are coupled to more lossy bands and a fundamental mode, at a high symmetry point, is coupled to a less lossy band of the photonic structure.

2. The surface-emitting, single mode laser of claim 1, wherein the photonic structure is implemented using a photonic crystal.

3. The surface-emitting, single mode laser of claim 1, wherein the cavity mode-dependent scaling of losses is enabled by a simultaneous implementation of an open-Dirac cone and truncations forming boundaries of the photonic structure.

4. The surface-emitting, single mode laser of claim 1, wherein the gain medium comprises at least one of a quantum well, a quantum dot, a quantum wire, and an organic molecule.

5. The surface-emitting, single mode laser of claim 1, wherein the gain medium comprises at least one of GaAs, AlGaAs, InGaAs, InGaAsP, GaN, Si, Ge, GaP, InAlGaN, InAs, InSb and SiN.

6. The surface-emitting, single mode laser of claim 1, wherein the photonic structure supports propagation of a single mode of the electromagnetic wave in a plane of the photonic crystal.

7. The surface-emitting, single mode laser of claim 4, wherein the single mode is a first mode from a center of a Brillouin zone of the photonic structure.

8. The surface-emitting, single mode laser of claim 1, wherein a mode spacing between consecutive cavity modes is a complex number.

9. The surface-emitting, single mode laser of claim 8, wherein the photonic crystal includes an aperture and the real part of the mode spacing scale as 1/N with a linear dispersion, where N is a size of the aperture or a number of unit-cells across a diagonal of the aperture such that for a unit-cell of length a, the aperture has a diagonal of size Na.

10. The surface-emitting, single mode laser of claim 9, wherein an imaginary part of the mode spacing scales as γᵢ=cᵢN⁻¹+dᵢN⁻² where “i” is a mode number and c₂>c₁, thereby making higher order modes more lossy than the fundamental mode.

11. The surface-emitting, single mode laser of claim 9, wherein all modes are symmetry protected modes with high quality factors but truncation dependent scaling

12. The surface-emitting, single mode laser of claim 10, wherein ci are controlled by a symmetry of the photonic structure and its truncation.

13. The surface-emitting, single mode laser of claim 9, wherein N is between 5 for smaller aperture to N=1 million for larger apertures.

14. The surface-emitting, single mode laser of claim 1, wherein an open-Dirac dispersion is tuned from quadratic to linear by overlapping at least two modes of different symmetries.

15. The surface-emitting, single mode laser of claim 12, wherein the truncations of the crystal are arranged to be more favorable to one of the modes and less favorable to another of the modes.

16. The surface-emitting, single mode laser of claim 12, wherein the truncations of the crystal are arranged to match a symmetry of the fundamental mode at a unit-cell level.

17. The surface-emitting, single mode laser of claim 12, wherein the aperture with N elements along its diagonal defines an area that couples energy out of the surface-emitting, single mode laser for lasing.

18. The surface-emitting, single mode laser of claim 1, wherein a unit-cell of the photonic structure is arranged so that an infinite structure exhibits a Dirac point involving at least two bands by overlapping symmetry-protected modes that have different symmetries.

19. The surface-emitting, single mode laser of claim 2, wherein the photonic crystal has at least two refractive index n₁ and n₂, a period and a pattern, where a pattern geometry is modified so that dispersion is tuned to linear.

20. The surface-emitting, single mode laser of claim 19, wherein the pattern is modified so that it has six-fold symmetry.

21. The surface-emitting, single mode laser of claim 19, wherein the pattern is circular.

22. The surface-emitting, single mode laser of claim 18, wherein the Dirac point induces mixing between the two bands away from the high symmetry point to thereby add loss to higher order modes originating from the less lossy band.

23. The surface-emitting, single mode laser of claim 2, wherein the photonic crystal defines a plurality of holes of any shape having a rotational symmetry that is the same as the lattice and a refractive index different from a refractive index of the lattice.

24. The surface-emitting, single mode laser of claim 2, wherein the photonic crystal defines a plurality of rods of any shape having a rotational symmetry that is the same as the lattice and a refractive index different from a refractive index of a surrounding environment.

25. The surface-emitting, single mode laser of claim 23 wherein the holes or rods are arranged in at least one of an oblique lattice, a rectangular lattice, a rhombic lattice, a square lattice, or a hexagonal lattice.

26. The surface-emitting, single mode laser of claim 9, wherein the period a is about 50 nm to 5 mm and the electromagnetic wave has a wavelength λ and the photonic structure has a thickness of λ/20 to 20 λ.

27. The surface-emitting, single mode laser of claim 1, further comprising: at least one electrode in contact with the photonic structure and the gain medium to inject current laterally and stimulate emission of the electromagnetic wave.

28. The surface-emitting, single mode laser of claim 1, further comprising: at least one electrode in contact with conductive materials to vertically inject current in the photonic structure and the gain medium and stimulate emission of the electromagnetic wave.

29. (canceled)

30. (canceled)

31. (canceled)

32. (canceled)

33. (canceled)

34. (canceled)

35. (canceled)

36. (canceled)

37. (canceled)

38. (canceled)

39. (canceled)

40. (canceled)

41. (canceled)

42. (canceled)

43. (canceled)

44. (canceled)

45. (canceled)

46. (canceled)

47. (canceled)

48. The surface-emitting, single mode laser of claim 1, further comprising packaging for the gain medium and the photonic structure, the packaging including a heat extraction layer.

49. The surface-emitting, single mode laser of claim 48, wherein the packaging is configured for optical pumping of the gain medium.

50. The surface-emitting, single mode laser of claim 1, wherein the packaging is configured for electrical pumping of the gain medium.

51. The surface-emitting, single mode laser of claim 27, wherein a metallization layer for electrical injection are selected from a group of materials including gold, gold alloys, platinum, nickel, and nickel alloys.

52. The surface-emitting, single mode laser of claim 1, further comprising a cooling arrangement that includes a plurality of non-conductive materials having a thermal conductivity that extracts heat from the surface-emitting, single mode laser.

53. The surface-emitting, single mode laser of claim 1, wherein the high symmetry point is a center of a Brillouin zone.
